(19) United States
(12) Patent Application Publication
(10) Pub. No.: US 2026/0324090 A1
(43) Pub. Date: Oct. 15, 2026

(54) INTEGRATED CIRCUIT DEVICE AND METHOD

(71) Applicant: TAIWAN SEMICONDUCTOR MANUFACTURING COMPANY, LTD., Hsinchu (TW)

(72) Inventors: Amit KUNDU, Hsinchu (TW); Yung-Shun CHEN, Hsinchu (TW); Hung-Yu CHEN, Hsinchu (TW); Shun-Chin TAI, Hsinchu (TW); Yung-Chow PENG, Hsinchu (TW)

(21) Appl. No.: 19/317,762

(22) Filed: Sep. 3, 2025

Related U.S. Application Data
(60) Provisional application No. 63/786,433, filed on Apr. 10, 2025.

(51) Int. Cl. H10D 89/10; H01L 23/528

(52) U.S. Cl. CPC H10D 89/10; H10W 20/43

(57) ABSTRACT

An integrated circuit (IC) device includes an array of subcircuit unit cells (SUCs) having a same SUC configuration. The SUC configuration includes a first number of P-type active regions and a different, second number of N-type active regions. The array of SUCs includes: first SUCs configuring a first subcircuit of an analog circuit, and second SUCs configuring a second subcircuit of the analog circuit, the second subcircuit different from the first subcircuit.

### RELATED APPLICATION(S)

This application claims the benefit of U.S. Provisional Application No. 63/786,433, filed Apr. 10, 2025, which is herein incorporated by reference in its entirety.

### BACKGROUND

An integrated circuit (“IC”) device includes one or more semiconductor devices represented in an IC layout diagram (also referred to as “layout diagram”, “layout”, or “IC layout”). An IC layout is hierarchical and includes modules which carry out higher-level functions in accordance with the semiconductor device's design specifications. The modules are often built from a combination of cells, each of which represents one or more semiconductor devices configured to perform a specific function. Cells having pre-designed layout diagrams are stored in cell libraries (sometimes referred to as “libraries” for simplicity) and accessible by various tools, such as electronic design automation (EDA) tools, to generate, optimize and verify designs for ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a functional flow chart of an IC design flow, in accordance with some embodiments.

FIGS. 2A, 2B, 2C, 2D are circuit diagrams of various analog circuits in IC devices, in accordance with some embodiments.

FIGS. 3A, 3B, 3C are schematic views of layouts of various subcircuit unit cells (SUCs), in accordance with some embodiments.

FIG. 3D includes schematic views of various SUC configurations, in accordance with some embodiments.

FIGS. 4A, 4B, 4C are schematic views of one or more layouts of various IC devices, in accordance with some embodiments.

FIG. 5 includes schematic views of a layout of an SUC and a layout of a corresponding back-end-of-line (BEOL) cell, in accordance with some embodiments.

FIG. 6 is a schematic cross-sectional view of an IC device, in accordance with some embodiments.

FIG. 7 is a flow chart of a portion of an IC design flow, in accordance with some embodiments.

FIGS. 8A, 8B are flowcharts of various methods, in accordance with some embodiments.

FIG. 9 is a block diagram of an electronic design automation (EDA) system in accordance with some embodiments.

FIG. 10 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

IC devices include both analog circuits and digital circuits configured to provide various functions and/or address various issues. In some embodiments, an analog circuit comprises different subcircuits all of which are implemented on identical subcircuit unit cells (SUCs) of the same SUC configuration. This configuration differs from other approaches in which each subcircuit is implemented by a separate cell in a separate circuit region. For example, in the other approaches, decoupling capacitor (decap or dcap) cells configuring decoupling capacitors are all arranged in a circuit region surrounded by a non-circuit region, current mirror cells configuring current mirrors are all arranged in another, separate circuit region surrounded by a further non-circuit region, or the like. The area occupied by the non-circuit regions is large in the other approaches. In contrast, in some embodiments, various subcircuits such as decoupling capacitors, inverters, current mirrors, or the like, are all implemented on identical SUCs in the same circuit region. In at least one embodiment, a single dummy region surrounds the circuit region with various subcircuits therein. As a result, it is possible in one or more embodiments in an IC device to reduce the area of dummy regions or non-circuit regions, which are not electrically coupled or configured to perform a function of the IC device. Besides the described chip area improvement, some embodiments achieve further improvements including, but not limited to, improved design uniformity, autonomous design process flow, mitigated density gradient effect (DGE), reduced parasitic resistance and/or capacitance (RC), shorter interconnects with improved performance (speed), or the like. Further advantages and/or effects are achievable in one or more embodiments as described herein.

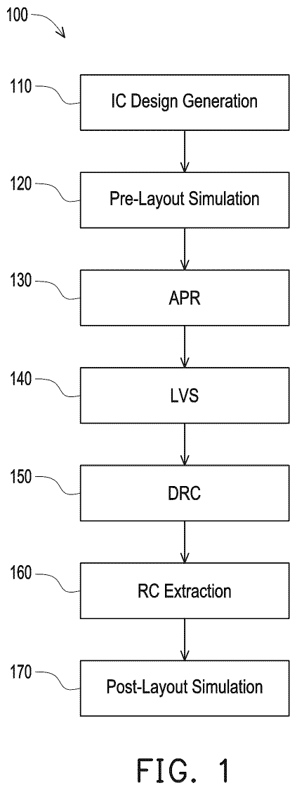

FIG. 1 is a functional flow chart of an IC design flow 100 in accordance with some embodiments.

In at least one embodiment, the IC design flow 100 utilizes one or more electronic design automation (EDA) tools (or systems) for testing a design of an IC device (sometimes simply referred to as “IC”) before manufacturing. The EDA tools, in some embodiments, comprise one or more sets of executable instructions for execution by at least one processor or controller or programmed computer to perform the indicated functionality. In at least one embodiment, the IC design flow 100 is performed by a design house of an IC manufacturing system discussed herein. In the example configuration in FIG. 1, the IC design flow 100 comprises operations 110-170.

At operation 110, a design of an IC is provided or generated, e.g., by a circuit designer. In some embodiments, the design of the IC includes an IC schematic, i.e., an electrical diagram, of the IC. In some embodiments, the IC schematic is generated or provided in the form of a schematic netlist, such as a Simulation Program with Integrated Circuit Emphasis (SPICE) netlist. Other data formats for describing the design are usable in some embodiments.

At operation 120, a pre-layout simulation is performed, e.g., by an EDA tool, on the design to determine whether the design meets a predetermined specification. If the design does not meet the predetermined specification, the IC is redesigned. In some embodiments, a SPICE simulation is performed on the SPICE netlist. Other simulation tools are usable, in place of or in addition to the SPICE simulation, in other embodiments.

At operation 130, a layout (or IC layout) of the IC is generated based on the design. The IC layout comprises the physical positions of various circuit elements (or devices) of the IC as well as the physical positions of various nets and vias interconnecting the circuit elements. In some embodiments, the IC layout is generated in the form of a Graphic Design System (GDS) file or GDSII file by an EDA tool. Other data formats for describing the IC layout of the IC are within the scope of various embodiments. For example, in one or more embodiments, the IC layout is generated and/or output in the form of an Open Artwork System Interchange Standard (OASIS) file, or a Design Framework II (DFII) file. For simplicity, non-limiting examples are provided herein for IC layouts included in GDS files.

In some embodiments, the IC layout is generated at operation 130 by an EDA tool or EDA system, such as an Automatic Placement and Routing (APR) tool. The APR tool receives the design of the IC in the form of a netlist as described herein, and performs a placement operation (or placement). For example, cells configured to provide pre-defined functions and having pre-designed layouts are stored in at least one library on at least one non-transitory computer-readable medium. The APR tool accesses various cells from the at least one library, and places the cells in an abutting manner to generate an IC layout corresponding to the IC schematic. Example cells include, but are not limited to, inverters, adders, multipliers, logic gates, phase lock loops (PLLs), flip-flops, multiplexers, memory cells, combinations thereof, or the like. Example logic gates include, but are not limited to, an AND, OR, NAND, NOR, XOR, INV, AND-OR-Invert (AOI), OR-AND-Invert (OAI), MUX, Flip-flop, BUFF, Latch, delay, clock cells, or the like. In some embodiments, a cell includes one or more active or passive circuit elements. Examples of active circuit elements (sometimes referred to as “semiconductor devices”) include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), FinFETs, planar MOS transistors with raised source/drains, nanosheet FETs, nanowire FETs, complementary field effect transistors (CFETs), or the like. Examples of diodes include, but are not limited to, varactors, or the like. Examples of passive circuit elements include, but are not limited to, capacitors, inductors, fuses, and resistors.

The APR tool then performs a routing operation (or routing) to route various nets and vias interconnecting the placed circuit elements. Examples of nets include, but are not limited to, conductive pads, conductive patterns, and conductive redistribution layers, or the like. The routing operation is performed to ensure that the routed interconnections satisfy a set of constraints. After the routing operation, the APR tool outputs the IC layout including the placed circuit elements and the routed nets and vias, in a GDS file as described herein. Nets and vias are commonly referred to herein as routing features. The described APR operation is an example. Other arrangements are within the scope of various embodiments. For example, in one or more embodiments, one or more of the described operations are omitted.

At operation 140, a layout-versus-schematic (LVS) check, is performed. The LVS check is performed to ensure that the generated IC layout corresponds to the design. Specifically, an LVS checking tool, i.e., an EDA tool or EDA system, recognizes, or extracts, electrical components as well as connections therebetween from the patterns of the generated IC layout. The LVS checking tool then generates a layout netlist representing the recognized electrical components and connections. The layout netlist generated from the IC layout is compared, by the LVS checking tool, with the schematic netlist (sometimes referred to as “source netlist”) of the design. If the two netlists match, e.g., within a matching tolerance, the LVS check is passed. Otherwise, correction is made to at least one of the IC layout or the design by returning the process to operation 110 and/or operation 130. Other verification processes are usable in some embodiments.

At operation 150, a design rule check (DRC) is performed, e.g., by an EDA tool, on the GDS file including the IC layout, to ensure that the IC layout satisfies certain manufacturing design rules, i.e., to ensure manufacturability of the IC. If one or more design rules is/are violated, correction is made to at least one of the IC layout or the design by returning the process to operation 110 and/or operation 130. Examples of design rules include, but are not limited to, a width rule which specifies a minimum width of a pattern in the IC layout, a spacing rule which specifies a minimum spacing between adjacent patterns in the IC layout, an area rule which specifies a minimum area of a pattern in the IC layout, a metal-to-via spacing rule which specifies a minimum spacing between a metal pattern and an adjacent via, a metal-to-metal spacing rule, or the like. Other verification processes are usable in some embodiments.

At operation 160, a resistance and capacitance (RC) extraction is performed, e.g., by an EDA tool, to determine parasitic parameters, e.g., parasitic resistance and parasitic capacitance, of interconnects in the IC layout for timing simulations in a subsequent operation. Other verification processes are usable in some embodiments.

At operation 170, a post-layout simulation is performed by a simulation tool, i.e., an EDA tool, to determine, taking the extracted parasitic parameters into account, whether the IC layout meets a predetermined specification. If the simulation indicates that the IC layout does not meet the predetermined specification, e.g., if the parasitic parameters cause undesirable delays, correction is made to at least one of the IC layout or the design by returning the process to operation 110 and/or operation 130. Otherwise, the IC layout is passed to manufacture or additional verification processes. In some embodiments, the IC layout before modification and/or the modified IC layout and/or the final IC layout for manufacture are stored on a non-transitory computer-readable medium.

In some embodiments, one or more of the described operations are omitted. In an example, one or more of the pre-layout simulation in operation 120, the RC extraction in operation 160, and the post-layout simulation in operation 170 is/are omitted, in one or more embodiments. Other arrangements are within the scopes of various embodiments. For simplicity, various operations and/or determinations are described herein as being performed by an APR tool. However, in at least one embodiment, one or more of the described operations and/or determinations are performed outside an APR tool, e.g., by one or more further automated systems, one or more processors, and/or one or more computer systems.

In some embodiments, the IC schematic at operation 110 comprises both digital circuits and analog circuits, and the APR tool at operation 130 is configured to generate a layout comprising circuit regions containing the digital circuits and further circuit regions containing the analog circuits.

In at least one embodiment, a transistor in a digital circuit is controllably switched to be either turned OFF or turned ON in a binary manner. For example, a voltage on a gate of the transistor is controllably switched between a first reference voltage (e.g., a first power supply voltage, such as, VDD) and a second reference voltage (e.g., a second power supply voltage, such as, VSS) to turn ON/OFF the transistor. When the transistor is turned ON, a given portion of a substrate corresponding to a channel of the transistor is substantially completely depleted of the majority carriers of the substrate and becomes a depletion region. When the channel is formed/induced, the depletion region is also temporarily augmented with the minority carriers of the substrate, i.e., the density of minority carriers in the depletion region is temporarily increased, which temporarily forms or induces a conductive channel in the substrate. The corresponding mode of operation of the transistor is depletion mode or saturation mode.

In at least one embodiment, a transistor in an analog circuit is configured and/or controlled such that an amount of current that flows through the transistor, i.e., the degree to which the transistor is turned ON, is varied in a continuous manner. The continuous/analog manner of controlling the current flow in a transistor of an analog circuit contrasts with the binary manner in which current is controlled to flow through a transistor in a digital circuit. For example, a temporary current flow through a transistor in an analog circuit is continuously varied in proportion to a gate voltage on the gate of the transistor, such that the corresponding mode of operation of the transistor is ohmic mode. More particularly, the degree to which the depletion region becomes depleted varies in proportion to the magnitude of the gate voltage, and ranges from being substantially incompletely depleted to being substantially completely depleted. In the ohmic mode, the gain of the transistor is sensitive to the potential difference between the gate voltage and a substrate voltage of the substrate, and a change in the substrate voltage has an effect on the degree to which the depletion region becomes depleted and thus the amount of current conducted through the channel.

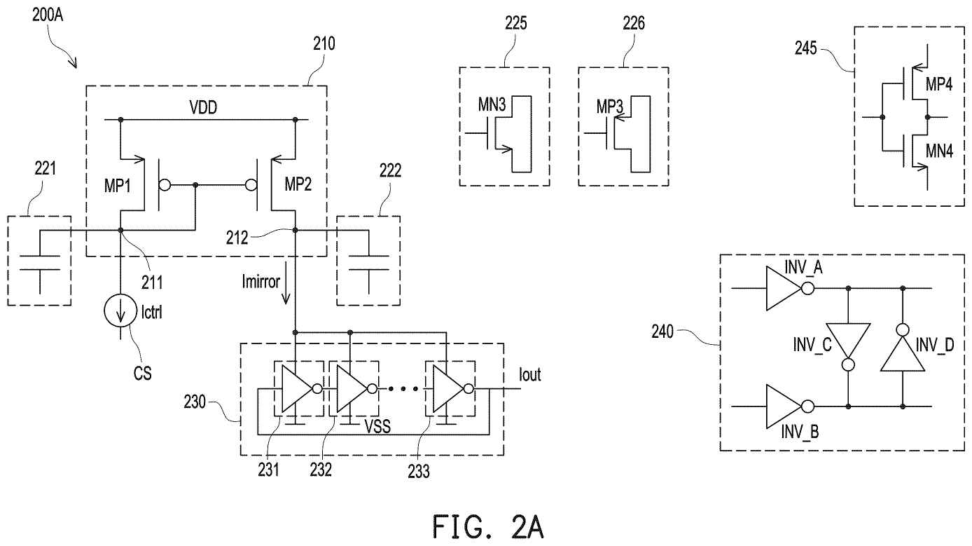

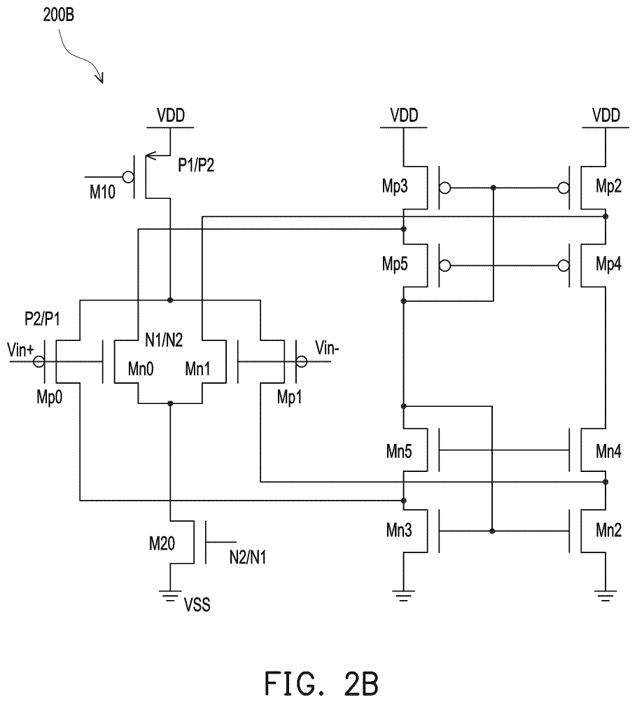

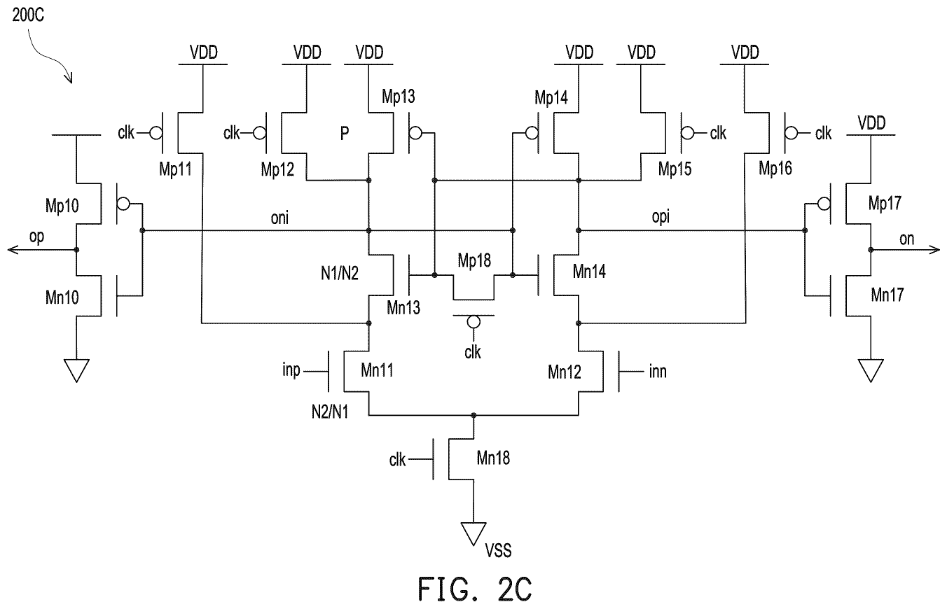

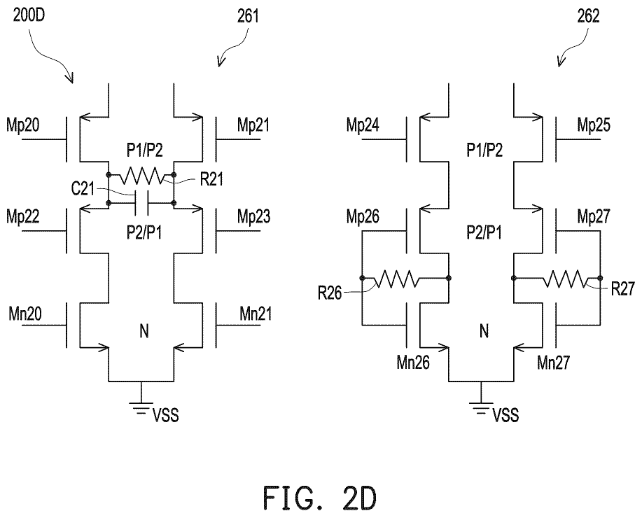

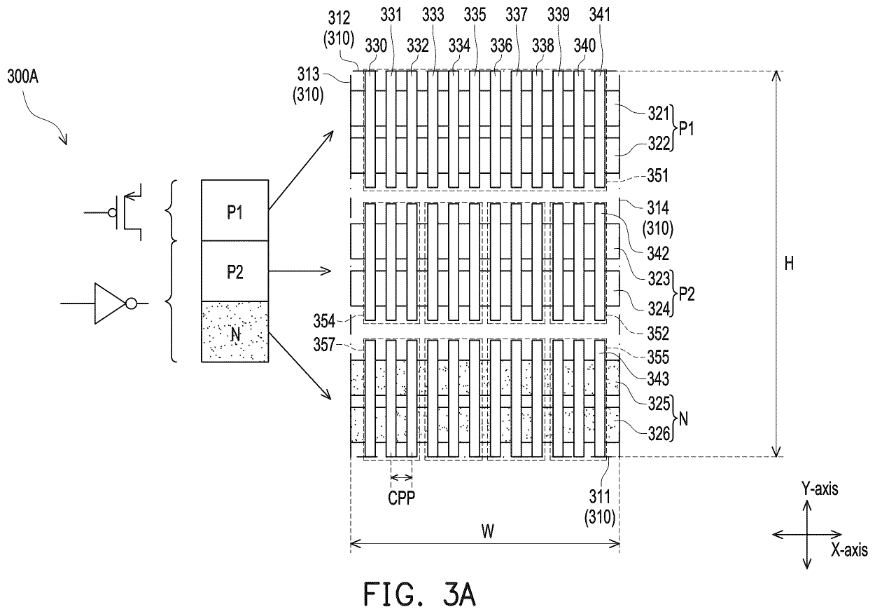

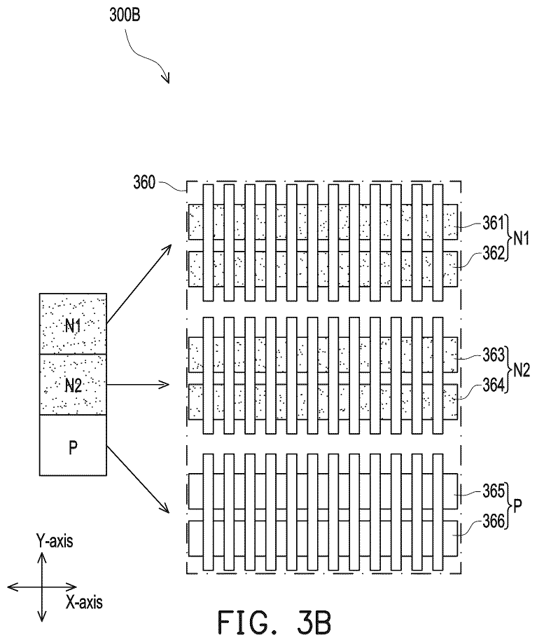

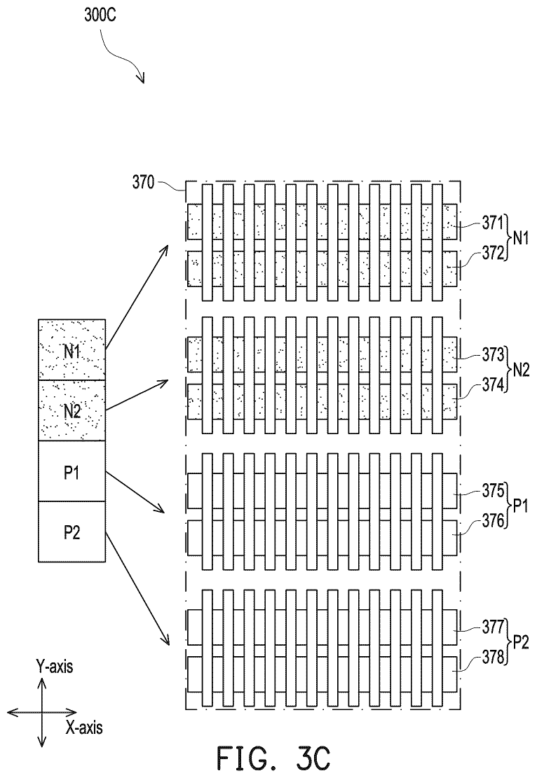

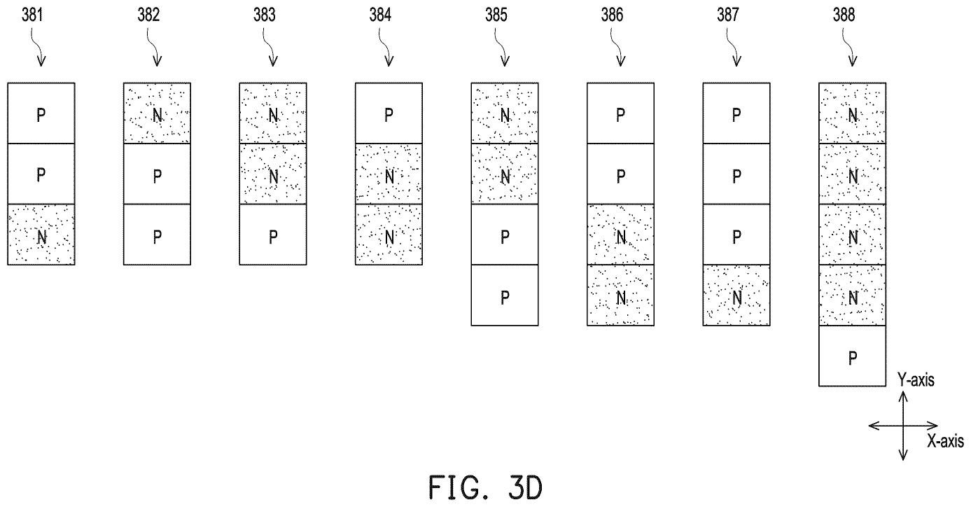

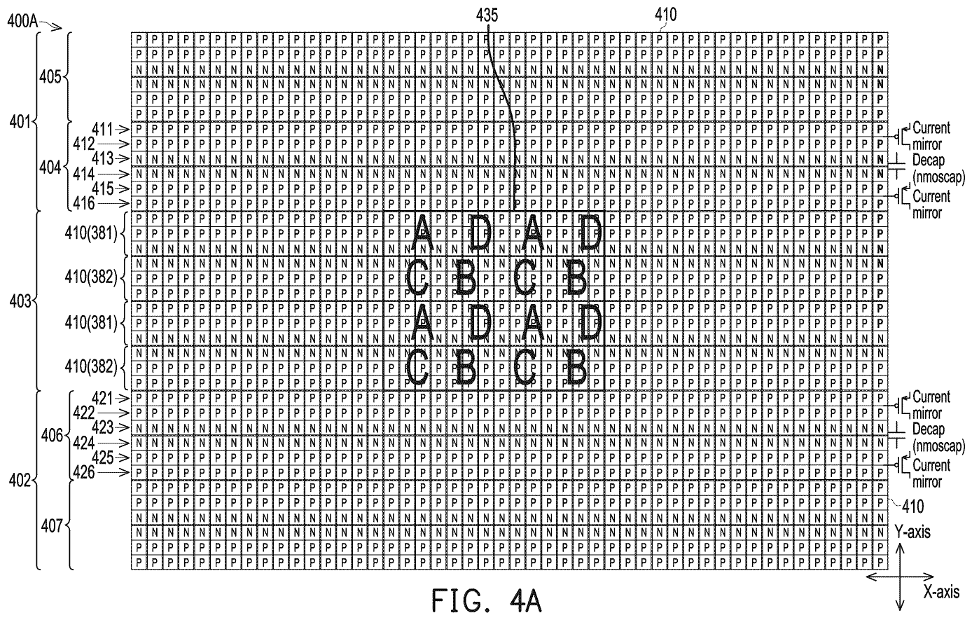

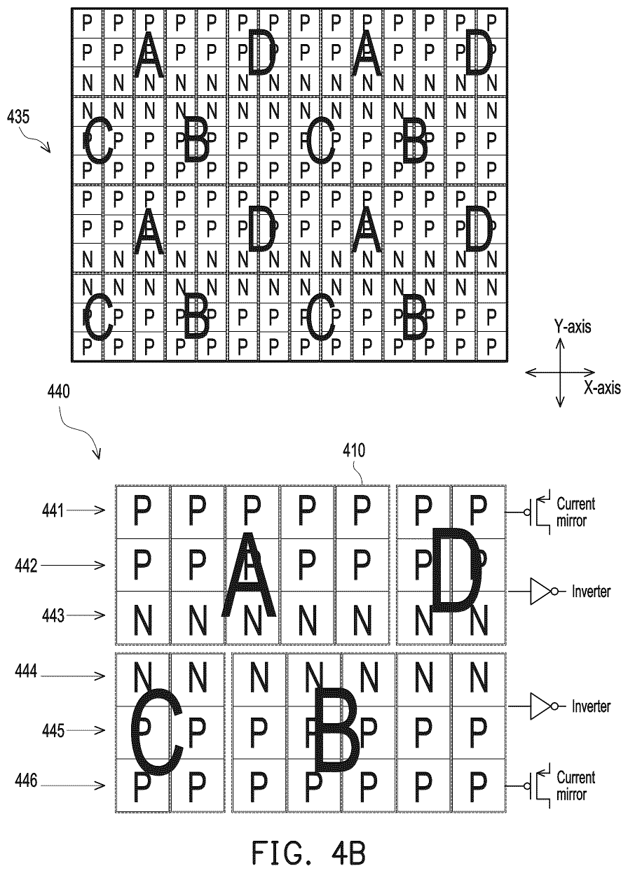

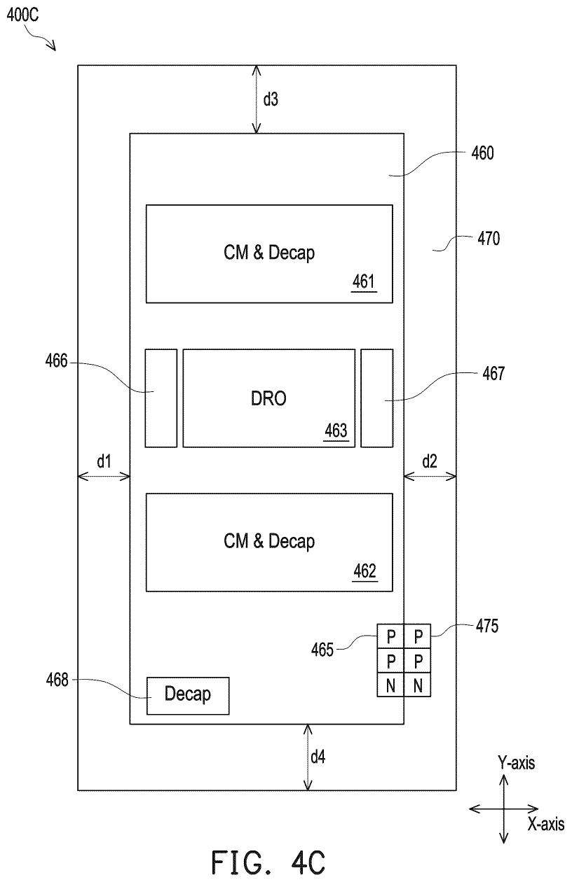

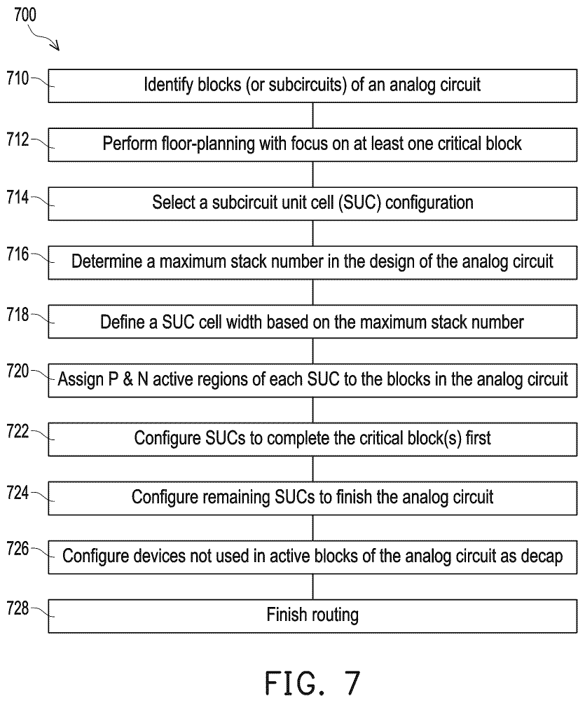

Examples of analog circuits in accordance with some embodiments are described with respect to FIGS. 2A-2D. Examples of SUCs and SUC configurations for implementing subcircuits of analog circuits in accordance with some embodiments are described with respect to FIGS. 3A-3D. Examples of one or more IC layouts including one or more analog circuits implemented on one or more SUCs in accordance with some embodiments are described with respect to FIGS. 4A-4C. Examples of one or more APR operations using one or more SUCs to generate one or more circuit regions containing analog circuits in accordance with some embodiments are described with respect to FIG. 7.

FIG. 2A is a circuit diagram of an example analog circuit in an IC device, in accordance with some embodiments. The example analog circuit in FIG. 2A is a current-controlled oscillator (ICO) 200A.

The ICO 200A comprises a current mirror 210, decoupling capacitors 221, 222, and a differential ring oscillator (DRO) 230. The current mirror 210, decoupling capacitors 221, 222, DRO 230 are electrically coupled to form the ICO 200A, and are examples of subcircuits of analog circuits.

The current mirror 210 comprises P-type transistors MP1, MP2. In analog circuits described herein with respect to some example embodiments, P-type transistors are p-channel metal-oxide semiconductor (PMOS) transistors, and N-type transistors are n-channel metal-oxide semiconductor (NMOS) transistors. Other transistor configurations are within the scopes of various embodiments. Each of the transistors MP1, MP2 has a first source/drain coupled to VDD, and a second source/drain 211, 212 coupled to the corresponding decoupling capacitor 221, 222. The second source/drain 211 of the transistor MP1 is further coupled to gates of the transistors MP1, MP2, and to a current source CS. In some embodiments, the current source CS is not a part of the ICO 200A and is configured to provide a substantially constant current Ictrl that is, in one or more embodiments, dynamically controllable to compensate for voltage, temperature, and/or process variations. The current mirror 210 is configured to generate a mirror current Imirror of the current Ictrl, and output the current Imirror from the second source/drain 212 of the transistor MP2 to the DRO 230.

Each of the decoupling capacitors 221, 222 has a first end (or terminal) coupled to the second source/drain of the corresponding transistor MP1, MP2, and a second end. In some embodiments, the second end of each of the decoupling capacitors 221, 222 is coupled to a conductor of a reference voltage, e.g., a power rail configured to carry VDD or VSS. In at least one embodiment, at least one of the decoupling capacitors 221, 222 is configured by a transistor having source/drains electrically coupled together. A decoupling capacitor configured by a P-type transistor is referred to as a P-type decoupling capacitor (or pmoscap), and a decoupling capacitor configured by an N-type transistor is referred to as an N-type decoupling capacitor (or nmoscap). An example N-type decoupling capacitor is a decoupling capacitor 225 which is configured by a transistor MN3. A gate of the transistor MN3 corresponds to one end of the decoupling capacitor 225. The source/drains of the transistor MN3 are coupled to each other, correspond to the other end of the decoupling capacitor 225, and is coupled in one or more embodiments to VSS. An example P-type decoupling capacitor is a decoupling capacitor 226 which is configured by a transistor MP3. A gate of the transistor MP3 corresponds to one end of the decoupling capacitor 226. The source/drains of the transistor MP3 are coupled to each other, correspond to the other end of the decoupling capacitor 226, and is coupled in one or more embodiments to VDD.

The DRO 230 comprises a plurality of inverter stages 231, 232, . . . 233 coupled into a ring shape. In the example configuration in FIG. 2A, three inverter stages are illustrated. Other numbers of inverter stages are within the scopes of various embodiments. In the DRO 230, an input of an inverter stage is coupled to an output of another inverter stage. For example, an input of the inverter stage 232 is coupled to an output of the inverter stage 231, an input of the inverter stage 231 is coupled to an output of the inverter stage 233, or the like. The current Imirror is supplied to the DRO 230 to power the inverter stages 231, 232, . . . 233 which are configured to generate an output current Iout at the output of the inverter stage 233.

In the example configuration in FIG. 2A, at least one of the inverter stages 231, 232, . . . 233 has a configuration of an inverter stage 240 which comprises inverters INV_A, INV_B, INV_C, INV_D. Inputs of the inverters INV_A, INV_B are differential inputs corresponding to the input of one inverter stage among the inverter stages 231, 232, . . . 233. Outputs of the inverters INV_C, INV_D are differential outputs corresponding to the output of the one inverter stage among the inverter stages 231, 232, . . . 233. An output of the inverter INV_A is coupled to an input of the inverter INV_C and the output of the inverter INV_D. An output of the inverter INV_B is coupled to an input of the inverter INV_D and the output of the inverter INV_C. At least one of the inverters INV_A, INV_B, INV_C, INV_D has a configuration of an inverter 245 which comprises a P-type transistor MP4 and an N-type MN4. A gate of the P-type transistor MP4 is coupled to a gate of the N-type MN4, and a source/drain of the P-type transistor MP4 is coupled to a source/drain of the N-type MN4. The inverters INV_A, INV_B configure a delay cell, the inverters INV_C, INV_D configure a latch. The described configurations of the DRO 230 and/or the inverter stage 240 are examples. Other ring oscillator configurations are within the scopes of various embodiments. For example, in one or more embodiments, each of the inverter stages 231, 232, . . . 233 includes an inverter, resulting in a single-ended ring oscillator. Various inverter stages and inverters described herein are further examples of subcircuits of analog circuits.

In some embodiments, the ICO 200A is implemented by SUCs having a PPN (or NPP) configuration, as described with respect to one or more of FIGS. 3A, 3D, 4A, 4B.

FIG. 2B is a circuit diagram of an example analog circuit in an IC device, in accordance with some embodiments. The example analog circuit in FIG. 2B is an operational transconductance amplifier (OTA) 200B.

The OTA 200B comprises P-type transistors M10, Mp0-Mp5, and N-type transistors N10, Mn0-Mn5. The transistors Mp0, Mp1 have gates correspondingly coupled to receive input signals Vin+, Vin−. First source/drains of the transistors Mp0, Mp1, M10 are coupled together. A second source/drain of the transistor M10 is coupled to VDD. The transistors Mn0, Mn1 have gates correspondingly coupled to receive the input signals Vin+, Vin−. First source/drains of the transistors Mn0, Mn1, M20 are coupled together. A second source/drain of the transistor M20 is coupled to VSS. The transistors Mp3, Mp5, Mn5, Mn3 are serially coupled between VDD and VSS. The transistors Mp2, Mp4, Mn4, Mn2 are serially coupled between VDD and VSS. A second source/drain of the transistor Mn0 is coupled to a source/drain of the transistor Mp3 and a source/drain of the transistor Mp5. A second source/drain of the transistor Mn1 is coupled to a source/drain of the transistor Mp2 and a source/drain of the transistor Mp4. A second source/drain of the transistor Mp0 is coupled to a source/drain of the transistor Mn3 and a source/drain of the transistor Mn5. A second source/drain of the transistor Mp1 is coupled to a source/drain of the transistor Mn2 and a source/drain of the transistor Mn4. Gates of the transistors Mp3, Mp2, Mn3, Mn2 are coupled to a source/drain of the transistor Mp5 and a source/drain of the transistor Mn5. Gates of the transistors Mp5, Mp4 are coupled together. Gates of the transistors Mn5, Mn4 are coupled together.

In some embodiments, the OTA 200B is implemented by SUCs having a PPNN (or NNPP) configuration with P-type active regions P1, P2, and N-type active regions N1, N2, as described with respect to one or more of FIGS. 3C, 3D. For example, the transistor M10 is implemented by one of the P-type active regions P1, P2 and one or more of the transistors Mp0-Mp5 are implemented by the other of the P-type active regions P1, P2, whereas the transistor M20 is implemented by one of the N-type active regions N1, N2 and one or more of the transistors Mn0-Mn5 are implemented by the other of the N-type active regions N1, N2. Other arrangements are within the scopes of various embodiments.

FIG. 2C is a circuit diagram of an example analog circuit in an IC device, in accordance with some embodiments. The example analog circuit in FIG. 2C is a sense amplifier (SA) comparator 200C.

The SA comparator 200C comprises P-type transistors Mp10-Mp18, and N-type transistors Mn10-Mn14, Mn17-Mn18. The transistors Mp10, Mn10 are coupled to form an inverter having an input coupled to a node oni, and an output op. The transistors Mp17, Mn17 are coupled to form an inverter having an input coupled to a node opi, and an output on. First source/drains of the transistors Mp11-Mp16 are coupled to VDD. Gates of the transistors Mp11, Mp12, Mp15, Mp16, Mp18, Mn18 are coupled to receive a clock signal clk. A gate of the transistor Mp13, second source/drains of the transistors Mp14, Mp15, a first source/drain of the transistor Mp18, and a gate of the transistor Mn13 are coupled to the node opi. A gate of the transistor Mp14, second source/drains of the transistors Mp12, Mp13, a second source/drain of the transistor Mp18, and a gate of the transistor Mn14 are coupled to the node oni. First source/drains of the transistors Mn13, Mn14 are correspondingly coupled to the node oni, opi. Second source/drains of the transistors Mp11, Mn13, Mn11 are coupled together. Second source/drains of the transistors Mp16, Mn14, Mn12 are coupled together. Gates of the transistors Mn11, MN12 are correspondingly coupled to receive input signals inp, inn. First source/drains of the transistors Mn11, MN12 are coupled to a first source/drain of the transistor Mn18. A source/drain of the transistor Mn18 is coupled to VSS.

In some embodiments, the SA comparator 200C is implemented by SUCs having a PNN (or NNP) configuration with a P-type active region P, and N-type active regions N1, N2, as described with respect to one or more of FIGS. 3B, 3D. For example, the transistors Mp10-Mp18 are implemented by the P-type active region P, whereas one or more of the transistors Mn10, Mn13, MN14, Mn17 are implemented by one of the N-type active regions N1, N2 and one or more of the transistors Mn11, Mn12, MN18 are implemented by the other of the N-type active regions N1, N2. Other arrangements are within the scopes of various embodiments.

FIG. 2D includes circuit diagrams of example analog circuits in an IC device, in accordance with some embodiments. The example analog circuits in FIG. 2D are part of a DDR (Double Data Rate) receiver (Rx) circuit 200D, and include a transadmittance amplifier (TAS) 261 and a transimpedance amplifier (TIA) 262.

The TAS 261 comprises P-type transistors Mp20-Mp23, N-type transistors Mn20, Mn21, a resistor R21, and a capacitor C21. The transistors Mp20, Mp22, Mn20 are serially coupled to VSS. The transistors Mp21, Mp23, Mn21 are serially coupled to VSS. First ends of the resistor R21 and the capacitor C21 are coupled to a source/drain of the transistor Mp20 and a source/drain of the transistor Mp22. Second ends of the resistor R21 and the capacitor C21 are coupled to a source/drain of the transistor Mp21 and a source/drain of the transistor Mp23.

The TIA 262 comprises P-type transistors Mp24-Mp27, N-type transistors Mn26, Mn27, and resistors R26, R27. The transistors Mp24, Mp26, Mn26 are serially coupled to VSS. The transistors Mp25, Mp27, Mn27 are serially coupled to VSS. The resistor R26 has a first end coupled to gates of the transistors Mp26, Mn26, and a second end coupled to a source/drain of the transistor Mp26 and a source/drain of the transistor Mn26. The resistor R27 has a first end coupled to gates of the transistors Mp27, Mn27, and a second end coupled to a source/drain of the transistor Mp27 and a source/drain of the transistor Mn27.

In some embodiments, at least one of the TAS 261 or the TIA 262 is implemented by SUCs having a PPN (or NPP) configuration with P-type active regions P1, P2, and an N-type active region N, as described with respect to one or more of FIGS. 3A, 3D. For example, one or more of the transistors Mp20, Mp21 are implemented by one of the P-type active regions P1, P2 and one or more of the transistors Mp22, Mp23 are implemented by the other of the P-type active regions P1, P2, whereas the transistors Mn20, Mn21 are implemented by the N-type active region N. For a further example, one or more of the transistors Mp24, Mp25 are implemented by one of the P-type active regions P1, P2 and one or more of the transistors Mp26, Mp27 are implemented by the other of the P-type active regions P1, P2, whereas the transistors Mn26, Mn27 are implemented by the N-type active region N. Other arrangements are within the scopes of various embodiments. The analog circuits described with respect to FIGS. 2A-2D are examples. Other analog circuits, such as a voltage-controlled oscillator, a digital-to-analog converter (DAC), a band-gap reference circuit, or the like, are within the scopes of various embodiments

FIG. 3A is a schematic view of a layout of an SUC 300A, in accordance with some embodiments. The SUC 300A has a PPN (or NPP) configuration with P-type active regions P1, P2, and an N-type active region N. In some embodiments, identical instances of the SUC 300A are placed in a layout of an IC device to implement different subcircuits of one or more analog circuits, as described with respect to FIG. 4A. In at least one embodiment, the SUC 300A is stored as a cell in a cell library on a non-transitory computer-readable medium.

The SUC 300A comprises a boundary 310 (i.e., a cell boundary) by which multiple instances of the SUC 300A are placed in abutment. The boundary 310 comprises edges 311, 312, 313, 314. The edges 311, 312 are elongated along an X axis, and the edges 313, 314 are elongated along a Y axis. In some embodiments, the X axis is an example of one of a first direction and a second direction, and the Y axis is an example of the other of the first direction and the second direction. The edges 311, 312, 313, 314 are connected together to form the closed boundary 310. In a place-and-route operation (also referred to as “automated placement and routing (APR)”) described herein, multiple instances of the SUC 300A are placed in abutment with each other at their respective boundaries in a layout of an IC device. The rectangular or square shape of the boundary 310 is an example.

The SUC 300A further comprises active regions P1, P2, N arranged consecutively along the Y axis. The active regions P1, P2, N are spaced from each other along the Y axis, and extend continuously along the X axis. In the example configuration in FIG. 3A, each of the active regions P1, P2, N comprises two portions spaced from each other along the Y axis. For example, the active region P1 comprises active region portions 321, 322, the active region P2 comprises active region portions 323, 324, the active region N comprises active region portions 325, 326. In at least one embodiment, each of the active region portions 321-326 corresponds to a nanosheet or a stack of nanosheets, and transistors configured by the active regions P1, P2, N are nanosheet transistors, such as nanosheet FETs. In some embodiments, the active regions described herein are active regions of CFETs in which a transistor or active region is stacked over another transistor or active region in a thickness direction of the IC device. Other active region configurations are within the scopes of various embodiments. Active regions are sometimes referred to as oxide-definition (OD) regions, and are schematically illustrated in the drawings with the label “OD.” The active regions P1, P2 are P-type active regions and configured to form P-type, e.g., PMOS, transistors. The active region N is an N-type active region and configured to form N-type, e.g., NMOS, transistors.

The SUC 300A further comprises gates over each of the active regions P1, P2, N. The gates are within the boundary 310. For simplicity, the gates over the active region P1 are designated as gates 330-341, whereas most of the gates over the active region P2 and the active region N are not numbered. A gate over the active region P1 is aligned along the Y axis with a corresponding gate over the active region P2 and a corresponding gate over the active region N. For example, the gate 341 over the active region P1 is aligned along the Y axis with a corresponding gate 342 over the active region P2 and a corresponding gate 343 over the active region N. Immediately adjacent gates are spaced from each other along the X axis by a gate pitch (CPP) which is a distance along the X axis between center lines of the immediately adjacent gates. Two gates are considered immediately adjacent (or directly adjacent) where there is no other gate therebetween. Each of the gates is a conductive gate that includes a conductive material, such as, polysilicon, and is schematically illustrated in the drawings with the label “PO.” Other conductive materials for the gates, such as metals, are within the scope of various embodiments. The gates configure, together with each of the active regions P1, P2, N, corresponding PMOS transistors or NMOS transistors. Gates are sometimes referred to as fingers, gate stacks, or stacks.

Transistors that are electrically coupled into a circuit or a subcircuit configured to perform a function of the IC device are referred to herein as functional transistors. Transistors that are not electrically coupled into a circuit or a subcircuit configured to perform a function of the IC device are referred to herein as dummy transistors. In at least one embodiment, a dummy transistor is identical to a functional transistor, except that the dummy transistor is not electrically coupled to another transistor, device or circuit. For example, a dummy transistor has a gate and source/drains which are electrically floating, or are electrically coupled together. In at least one embodiment, a dummy transistor has a dummy gate of a non-conductive material. Other dummy transistor configurations are within the scopes of various embodiments. In at least one embodiment, the SUC 300A is free of dummy transistors. In some embodiments, the SUC 300A further comprises a guard ring (not shown). In some embodiments, one or more of the guard rings disclosed herein includes one or more dummy transistors.

In some embodiments, all gates in the SUC 300A have a same width (e.g., gate width) along the X axis, and a same length (e.g., gate length) along the Y axis. The SUC 300A has a cell height H along the Y axis, and a cell width W along the X axis. The cell height H is a distance along the Y axis between the edges 311, 312. The cell width W is a distance along the X axis between the edges 313, 314. The cell height H depends on the gate length and the number of active regions (i.e., 3 active regions) in the SUC 300A. The cell width W depends on the gate width and the total number of gates (or fingers) over an active region. In the example configuration in FIG. 3A, the SUC 300A comprises 12 gates or 12 fingers over each of the active regions P1, P2, N. Other numbers of gates over each active region are within the scopes of various embodiments. In some embodiments, the gate width and the gate length are predetermined, e.g., by one or more fabricating processes, resulting in a predetermined cell height H. In at least one embodiment, the cell width W is customizable, e.g., automatically by a programmed processor and/or by a human designer specifying the total number of gates over each active region.

An SUC in accordance with some embodiments is configured to implement different subcircuits of one or more analog circuits. In the example configuration in FIG. 3A, the SUC 300A is configured to implement different subcircuits including at least one individual PMOS transistor and at least one inverter.

Specifically, the active region P1 is configured to form, together with the corresponding gates 330-341, a PMOS transistor 351 which is to be electrically coupled with another, identical PMOS transistor (not shown) of another SUC identical to the SUC 300A, to form a current mirror corresponding to the current mirror 210 described with respect to FIG. 2A. The transistor 351 comprises 12 gates (or fingers) which are all electrically coupled together by various conductive features as described herein to provide a driving strength of 12. In some embodiments, the gates or fingers of transistors in multiple SUCs are coupled together to form a transistor having a driving strength greater than the driving strength provided by the transistor(s) of a single SUC. The described number of fingers, or the driving strength, of the transistor 351 is an example, and is customizable, e.g., automatically by a programmed processor and/or by a human designer, in one or more embodiments.

The active region P2 and active region N are configured to form, together with the corresponding gates, corresponding PMOS transistors and NMOS transistors which, in turn, are electrically coupled by conductive features to form inverters corresponding to the inverter 245 described with respect to FIG. 2A. In the example configuration in FIG. 3A, the 12 fingers over the active region P2 are grouped into four groups or sets each having three fingers. As a result, four PMOS transistors each having a driving strength of 3 are formed. Two of the four PMOS transistors are designated as transistors 352, 354. Similarly, the 12 fingers over the active region N are grouped into four groups or sets each having three fingers. As a result, four NMOS transistors each having a driving strength of 3 are formed. Two of the four NMOS transistors are designated as transistors 355, 357. In at least one embodiment, the number of groups and/or the number of fingers in each group is/are customizable, e.g., automatically by a programmed processor and/or by a human designer. Each of the PMOS transistors configured by the active region P2 is electrically coupled by conductive features with a corresponding NMOS transistor configured by the active region N, to form an inverter. For example, the transistor 352 is coupled to the transistor 355 to form an inverter, the transistor 354 is coupled to the transistor 357 to form a further inverter, or the like.

In the example configuration in FIG. 3A, the SUC 300A is configurable to wholly or partly implement different subcircuits, such as a current mirror and inverters. The SUC 300A is configurable in a different manner to implement other subcircuits, such as a current mirror and one or more decoupling capacitors. In an example, the active region P2 and the corresponding gates are configurable as a single PMOS transistor with the driving strength of 12, similar to the transistor 351, to form with the transistor 351 a full current mirror. The active region N and the corresponding gates are configurable as one or more decoupling capacitors corresponding to the decoupling capacitor 225 described with respect to FIG. 2A. In a further example, the SUC 300A is configured to implement different subcircuits, for example, as described with respect to FIG. 2D. Other configurations are within the scopes of various embodiments. The flexibility with which the SUC 300A is configurable to implement various subcircuits in a single cell is an improvement over other approaches in which each subcircuit is implemented by a separate cell or each cell is configured to implement only one subcircuit.

FIG. 3B is a schematic view of a layout of an SUC 300B, in accordance with some embodiments. The SUC 300B has an NNP (or PNN) configuration with N-type active regions N1, N2, and a P-type active region P. In some embodiments, identical instances of the SUC 300B are placed in a layout of an IC device to implement different subcircuits of one or more analog circuits. In at least one embodiment, the SUC 300B is stored as a cell in a cell library on a non-transitory computer-readable medium.

The SUC 300B comprises a boundary 360 by which multiple instances of the SUC 300B are placed in abutment. In some embodiments, the boundary 360 corresponds to the boundary 310. The SUC 300B further comprises active regions N1, N2, P arranged consecutively along the Y axis and corresponding gates, which are configured similarly to the active regions and gates described with respect to FIG. 3A. For example, the active region N1 comprises active region portions 361, 362, the active region N2 comprises active region portions 363, 364, the active region P comprises active region portions 365, 366. The active regions N1, N2 are N-type active regions and configured to form, together with the corresponding gates, N-type, e.g., NMOS, transistors. The active region P is a P-type active region and configured to form, together with the corresponding gates, P-type, e.g., PMOS, transistors. In at least one embodiment, the SUC 300B is free of dummy transistors. In some embodiments, the SUC 300B further comprises a guard ring (not shown).

In some embodiments, in a manner similar to that described with respect to FIG. 3A, the number of gates over each active region in the SUC 300B and/or how the gates over each active region are grouped into one or more sets are customizable, e.g., automatically by a programmed processor and/or by a human designer. In at least one embodiment, the SUC 300B is configured to implement different subcircuits, for example, as described with respect to FIG. 2C. One or more advantages described with respect to the SUC 300A are achievable by the SUC 300B, in accordance with some embodiments.

FIG. 3C is a schematic view of a layout of an SUC 300C, in accordance with some embodiments. The SUC 300C has an NNPP (or PPNN) configuration with N-type active regions N1, N2, and P-type active regions P1, P2. In some embodiments, identical instances of the SUC 300C are placed in a layout of an IC device to implement different subcircuits of one or more analog circuits. In at least one embodiment, the SUC 300C is stored as a cell in a cell library on a non-transitory computer-readable medium.

The SUC 300C comprises a boundary 370 by which multiple instances of the SUC 300C are placed in abutment. In some embodiments, the boundary 370 corresponds to the boundary 310. The SUC 300C further comprises active regions N1, N2, P1, P2 arranged consecutively along the Y axis and corresponding gates, which are configured similarly to the active regions and gates described with respect to FIG. 3A. For example, the active region N1 comprises active region portions 371, 372, the active region N2 comprises active region portions 373, 374, the active region P1 comprises active region portions 375, 376, the active region P2 comprises active region portions 377, 378. The active regions N1, N2 are N-type active regions and configured to form, together with the corresponding gates, N-type, e.g., NMOS, transistors. The active regions P1, P2 are P-type active regions and configured to form, together with the corresponding gates, P-type, e.g., PMOS, transistors. In at least one embodiment, the SUC 300C is free of dummy transistors. In some embodiments, the SUC 300C further comprises a guard ring (not shown).

In some embodiments, in a manner similar to that described with respect to FIG. 3A, the number of gates over each active region in the SUC 300C and/or how the gates over each active region are grouped into one or more sets are customizable, e.g., automatically by a programmed processor and/or by a human designer. In at least one embodiment, the SUC 300C is configured to implement different subcircuits, for example, as described with respect to FIG. 2B. One or more advantages described with respect to the SUC 300A are achievable by the SUC 300C, in accordance with some embodiments.

FIG. 3D includes schematic views of various SUC configurations 381-388, in accordance with some embodiments. FIG. 3D is not an exhausted list of possible SUC configurations in accordance with various embodiments.

The SUC configuration 381 (PPN) and the SUC configuration 382 (NPP) are equivalents, and are considered as a same SUC configuration in one or more embodiments. An example of the SUC configurations 381, 382 is described with respect to FIG. 3A. The SUC configuration 383 (NNP) and the SUC configuration 384 (PNN) are equivalents, and are considered as a same SUC configuration in one or more embodiments. An example of the SUC configurations 383, 384 is described with respect to FIG. 3B. The SUC configuration 385 (NNPP) and the SUC configuration 386 (PPNN) are equivalents, and are considered as a same SUC configuration in one or more embodiments. An example of the SUC configurations 385, 386 is described with respect to FIG. 3C. The SUC configuration 387 (PPPN) and an equivalent SUC configuration (NPPP) (not shown), as well as equivalent SUC configurations NNNP and PNNN (not shown), serve as examples of further SUC configurations in one or more embodiments. The SUC configuration 388 (NNNNP) and an equivalent SUC configuration (PNNNN) (not shown), as well as equivalent SUC configurations PPPPN and NPPPP (not shown), serve as examples of other SUC configuration in accordance with some embodiments.

In some embodiments, a decision as to which SUC configuration is selected for SUCs to implement various subcircuits of one or more analog circuits is made automatically by a programmed processor and/or by a human designer. In at least one embodiment, such a decision is made based on the number and/or the required driving strength of PMOS transistors and/or NMOS transistors in the analog circuits to be implemented.

For example, to implement an analog circuit in which PMOS transistors are required in greater quantity and/or are required to provide greater driving strength than NMOS transistors, an SUC configuration including more P-type active regions than N-type active regions, e.g., one of the SUC configurations 381, 387, is selected. When the imbalance between the PMOS transistors and NMOS transistors of an analog circuit in terms of quantity and/or driving strength is low, the SUC configuration 381 is selected. When the imbalance between the PMOS transistors and NMOS transistors of an analog circuit in terms of quantity and/or driving strength is high, the SUC configuration 387 with a greater number of P-type active regions is selected.

Conversely, to implement an analog circuit in which NMOS transistors are required in greater quantity and/or are required to provide greater driving strength than PMOS transistors, an SUC configuration including more N-type active regions than P-type active regions, e.g., one of the SUC configurations 383, 388, is selected. When the imbalance between the NMOS transistors and PMOS transistors of an analog circuit in terms of quantity and/or driving strength is low, the SUC configuration 383 is selected. When the imbalance between the NMOS transistors and PMOS transistors of an analog circuit in terms of quantity and/or driving strength is high, the SUC configuration 388 with a greater number of N-type active regions is selected.

To implement an analog circuit in which the required quantity and driving strength of PMOS transistors are the same, or substantially the same, as NMOS transistors, an SUC configuration including an equal number of N-type active regions and P-type active regions, e.g., the SUC configuration 385, is selected. In some embodiments, the SUC configurations 381, 383, 385 are sufficient to implement all analog circuits in an IC device.

In some embodiments, identical SUCs having the selected SUC configuration, or multiple instances of the same SUC having the selected SUC configuration, are placed in a circuit region of a layout of an IC device to implement one or more analog circuits. A non-limiting specific example is described herein using the SUC configuration 381 (PPN) and the equivalent SUC configuration 382. Other SUC configurations are usable in a similar manner.

FIG. 4A is a schematic view of a layout 400A of an IC device, in accordance with some embodiments. In at least one embodiment, the layout 400A is generated by an APR tool and/or stored on a non-transitory computer-readable medium.

The layout 400A comprises an array of SUCs 410 having the same SUC configuration 381 or 382. In some embodiments, the array is obtained by placing multiple instances of the SUC 410 in multiple rows and multiple columns of the array. The rows are elongated along the X axis. The columns are elongated along the Y axis. In some embodiments, the SUC 410 corresponds to the SUC 300A and has 12 fingers over each active region. In at least one embodiment, the number of fingers over each active region in the SUC 410 is other than 12.

The array of SUCs 410 of the layout 400A is configured to implement different subcircuits of one or more analog circuits. In the example configuration in FIG. 4A, the array of SUCs 410 is configured to implement various subcircuits of one or more instances of the ICO 200A. Specifically, the array of SUCs 410 comprises regions 401-403 arranged along the Y axis. The region 401 is configured to implement the transistor MP1 of the current mirror 210 and the corresponding decoupling capacitor 221. The region 402 is configured to implement the transistor MP2 of the current mirror 210 and the corresponding decoupling capacitor 222. The region 403 is configured to implement the DRO 230.

The region 401 comprises subregions 404, 405. In some embodiments, the subregion 405 is configured similarly to the subregion 404. The subregion 404 comprises two immediately adjacent rows of SUCs 410. The two rows of SUCs 410 in the subregion 404 comprise four rows of P-type active regions corresponding to four rows 411, 412, 415, 416 of PMOS transistors, and two rows of N-type active regions corresponding to two rows 413, 414 of NMOS transistors. The PMOS transistors in the rows 411, 412, 415, 416 are configured as the transistor MP1 of the current mirror 210. The NMOS transistors in the rows 413, 414 are configured as the decoupling capacitor 221 which is an N-type decoupling capacitor (nmoscap) and is coupled to the transistor MP1 configured by the PMOS transistors in the rows 411, 412, 415, 416.

The region 402 comprises subregions 406, 407. In some embodiments, the subregion 407 is configured similarly to the subregion 406. The subregion 406 comprises two immediately adjacent rows of SUCs 410. The two rows of SUCs 410 in the subregion 406 comprise four rows of P-type active regions corresponding to four rows 421, 422, 425, 426 of PMOS transistors, and two rows of N-type active regions corresponding to two rows 423, 424 of NMOS transistors. The PMOS transistors in the rows 421, 422, 425, 426 are configured as the transistor MP2 of the current mirror 210. The NMOS transistors in the rows 423, 424 are configured as the decoupling capacitor 222 which is an N-type decoupling capacitor (nmoscap) and is coupled to the transistor MP2 configured by the PMOS transistors in the rows 421, 422, 425, 426.

The region 403 comprises at least one instance of a subregion 435 described in detail with respect to FIG. 4B. In at least one embodiment, the region 403 comprises multiple instances of the subregion 435. In some embodiments, all instances of the subregion 435 do not occupy the entire region 403, and portions of the region 403 on opposite sides of the instances of the subregion 435 are configured similarly to the regions 401, 402.

In FIG. 4B, the subregion 435 comprises a repeated pattern of a block 440 comprising a number of SUCs 410. The block 440 is constituted by subblocks A, B, C, D. The subblocks A, D belong to one row of SUCs 410, and the subblocks B, C belong to an immediately adjacent row of SUCs 410. Each of the subblocks A, B comprises five SUCs 410, and each of the subblocks C, D comprises two SUCs 410. Other numbers of SUCs 410s and/or rows of SUCs 410 in each subblock are within the scopes of various embodiments. The block 440 comprises four rows of P-type active regions corresponding to four rows 441, 442, 445, 446 of PMOS transistors, and two rows of N-type active regions corresponding to two rows 443, 444 of NMOS transistors. The PMOS transistors in the rows 441, 446 are configured as transistors for a current mirror. For example, the PMOS transistors in the row 441 are configured as the transistor MP1 of the current mirror 210, whereas the PMOS transistors in the row 446 are configured as the transistor MP2 of the current mirror 210.

The NMOS transistors in the rows 443, 444 and the corresponding PMOS transistors in the rows 442, 445 are configured as inverters corresponding to the inverter 245 described with respect to FIG. 2A. The inverters are coupled into a DRO corresponding to the DRO 230 described with respect to FIG. 2A. The block 440 and similar blocks are therefore also referred to as the DRO blocks. In some embodiments, the inverters in the subblock A are coupled to configure an inverter corresponding to the inverter INV_A, the inverters in the subblock B are coupled to configure an inverter corresponding to the inverter INV_B, the inverters in the subblock C are coupled to configure an inverter corresponding to the inverter INV_C, and the inverters in the subblock D are coupled to configure an inverter corresponding to the inverter INV_D, as described with respect to FIG. 2A. In a non-limiting example, the inverters INV_A, INV_B include a greater quantity of fingers and have a greater driving strength than the inverters INV_C, INV_D.

In some embodiments, inside the DRO blocks, the P-type active region for implementing a current mirror in each SUC (e.g., in the rows 441, 446 in FIG. 4B) is configured similarly to the active region P1 described with respect to FIG. 3A, i.e., with all 12 fingers in one set or group. The P-type active region and N-type active region for implementing an inverter in each SUC (e.g., in the rows 442-445 in FIG. 4B) are configured differently for the subblocks A, B and for the subblocks C, D. For example, the 12 fingers over each P-type active region or N-type active region in each SUC in the rows 442-445 are grouped into four groups each having three fingers for the subblocks A, B, and are grouped into six groups each having two fingers for the subblocks C, D. Other configurations are within the scopes of various embodiments.

In some embodiments, outside the DRO blocks, the P-type active regions for implementing a current mirror in each SUC (e.g., in the rows 411, 412, 415, 416, 421, 422, 425, 426 in FIG. 4A) is configured similarly to the active region P1 described with respect to FIG. 3A, i.e., with all 12 fingers in one set or group. The N-type active region for implementing a decoupling capacitor in each SUC (e.g., in the rows 413, 414, 423, 424 in FIG. 4A) are configured similarly to the active region N described with respect to FIG. 3A, i.e., with four groups each having three fingers. Other configurations are within the scopes of various embodiments.

In the example configurations in FIGS. 4A, 4B, the array of SUCs 410 comprises various SUCs 410 which are identical but are electrically coupled to configure different subcircuits of an analog circuit, e.g., an ICO. For example, the SUCs 410 having the active regions in the rows 411-413 in FIG. 4A are examples of an SUC that configures a current mirror and a decoupling capacitor, whereas the SUCs 410 having the active regions in the rows 441-443 in FIG. 4B are examples of a further SUC that configures a current mirror and an inverter. As a result, different subcircuits, e.g., decoupling capacitor, current mirror, inverter, DRO, are implemented in the array of SUCs 410.

In at least one embodiment, the array of SUCs 410 is free of dummy transistors that separate a subcircuit of an analog circuit from further subcircuits of the analog circuit. For example, the array of SUCs 410 is free of dummy transistors that separate the current mirror and/or the decoupling capacitor in the region 401 and/or the region 402 from the DRO in the region 403. In some embodiments, the array of SUCs 410 is free of dummy transistors that surround a subcircuit of the analog circuit. For example, the array of SUCs 410 is free of dummy transistors that surround the DRO and separate the DRO from the current mirror and the decoupling capacitor.

FIG. 4C is a schematic view of a layout 400C of an IC device, in accordance with some embodiments. In at least one embodiment, the layout 400C is generated by an APR tool and/or stored on a non-transitory computer-readable medium.

The layout 400C comprises a circuit region 460, and a dummy region 470 surrounding the circuit region 460. In some embodiments, the circuit region 460 corresponds to the array of SUCs 410 described with respect to FIG. 4A. For example, the circuit region 460 comprises regions 461, 462, 463 corresponding to the regions 401, 402, 403 in FIG. 4A. The regions 461, 462 are configured to implement current mirrors (CM) and decoupling capacitors (Decap), whereas the region 463 is configured to implement DROs. The circuit region 460 constitutes an array of SUCs 465. In some embodiments, the SUC 465 corresponds to the SUC 410. In at least one embodiment, the circuit region 460 is filled with SUCs 465 up to at least one, some, or all, of the four edges where the circuit region 460 touches the dummy region 470.

In some embodiments, not all SUCs 465 and/or not all transistors in one or more SUCs 465 are coupled into a particular subcircuit. For example, given a required driving strength and/or number of transistors in a specific DRO configuration, not all SUCs 465 in the rows containing the region 463 are used to configure a required DRO. Such “unused” SUCs 465 and/or “unused” transistors of one or more partially used SUCs 465 are configured as additional decoupling capacitors. In some embodiments, in the array of SUCs 410, transistors not configuring any subcircuit of the analog circuit (e.g., the ICO) are configured as additional decoupling capacitors. In at least one embodiment, an SUC 410 includes one or more first transistors configuring at least one subcircuit (e.g., current mirror, inverter, DRO) of the analog circuit (e.g., ICO), and one or more second transistors not configuring any subcircuit of the analog circuit. Such one or more second transistors are configured as additional decoupling capacitors.

In the example configuration in FIG. 4C, additional decoupling capacitors are arranged in regions 466, 467 on opposite sides of the region 463. A further region 468 including additional decoupling capacitors is also included in the circuit region 460 in the example configuration in FIG. 4C. The specifically illustrated arrangement of the regions 466-468 including additional decoupling capacitors is an example, and other arrangements are within the scopes of various embodiments depending on the actual designs of IC devices. In at least one embodiment, the regions 466, 467 are configured similarly to the regions 461, 462 and include not only decoupling capacitors, but also current mirrors. In some embodiments, additional decoupling capacitors are arranged not only in separate regions such as the regions 466-468, but are also spread at various locations among subcircuits other than decoupling capacitors in the circuit region 460. As a result, it is possible in one or more embodiments to increase the number of decoupling capacitors available in an IC device without requiring or increasing a dedicated chip area for decoupling capacitors.

In at least one embodiment, the circuit region 460 is free of dummy transistors that separate a subcircuit of an analog circuit from further subcircuits of the analog circuit. For example, the circuit region 460 is free of dummy transistors that separate the current mirror and/or the decoupling capacitor in the region 461 and/or the region 462 from the DRO in the region 463. In some embodiments, the circuit region 460 is free of dummy transistors that surround a subcircuit of the analog circuit. For example, the circuit region 460 is free of dummy transistors that surround the DRO in the region 463 and separate the DRO from the current mirror and the decoupling capacitor.

The dummy region 470 surrounds the circuit region 460 on all four sides. The dummy region 470 comprises dummy transistors as described herein. In the example configuration in FIG. 4C, the dummy region 470 is filled with multiple instances of an SUC 475; however, transistors of the SUCs 475 are not electrically coupled into a particular circuit. In some embodiments, the SUCs 475 have the same SUC configuration as the SUCs 465. In at least one embodiment, the SUCs 475 are identical to the SUCs 465. The dummy region 470 has widths d1-d4 on the corresponding edges of the circuit region 460. In some embodiments, the widths d1-d4 has predetermined values to avoid or mitigate the density gradient effect (DGE). In at least one embodiment, the widths d1-d4 are 5 μm or greater.

Currently, with continuous shrink in semiconductor technology, stringent process design rules restrict the gate lengths and/or widths usable for analog circuits. As analog circuits are restricted to few available gate lengths, a digital centric design and layout using uniform and single pattern is employed in accordance with some embodiments to achieve better area scaling. In at least one embodiment, CFETs are used to configure analog circuits in designs similar to designs of digital circuits. With the use of CFETs, it is possible in one or more embodiments to implement analog circuits with the scaling capability similar to that of digital circuit layouts.

In certain situations, a process development kit (PDK) from a foundry provides templates for individual PMOS transistors, individual NMOS transistors, and pairs of a NMOS transistor and a NMOS transistor. To meet various analog circuit key performance indicators (KPIs), e.g., matching, speed, noise, high decap, or the like, other approaches use different cells in different circuit blocks, resulting in a layout that is not uniform. In contrast to the other approaches which use different cells for different circuit blocks, an analog circuit in accordance with some embodiments is configured using multiple instances of a single cell, to achieve a uniform integrated layout approach.

Moreover, the other approaches use a large amount of chip area to create dummy surroundings around each circuit block. For example, in the other approaches, decoupling capacitor cells configuring decoupling capacitors are all arranged in a circuit region surrounded by a non-circuit region, current mirror cells different from the decoupling capacitor cells and configuring current mirrors are all arranged in another, separate circuit region surrounded by a further non-circuit region, or the like. The area occupied by non-circuit regions is disadvantageously large in the other approaches, potentially causing undesirably high IR drops (voltage drops). In contrast to the other approaches which require an individual dummy surrounding for each circuit block or circuit region, various subcircuits of an analog circuit in accordance with some embodiments are all implemented on identical SUCs in the same circuit region and, for avoiding or at least mitigating the density gradient effect (DGE), a single dummy region surrounds the circuit region with various subcircuits therein. As a result, it is possible in one or more embodiments to reduce the area of dummy regions or non-circuit regions in an IC device, while addressing DGE concerns and/or achieving improved process control. The area improvement in one or more embodiments is from about 20% to about 40%. In a non-limiting example, an ICO design as described with respect to one or more of FIGS. 2A, 3A, 4A, 4B, provides an area improvement of about 30% over the other approaches.

Examples of subcircuits constituting one or more analog circuits in accordance with some embodiments include, but are not limited to, individual P-type transistors, individual N-type transistors, P-type transistor arrays, N-type transistor arrays, P-type decoupling capacitors, N-type decoupling capacitors, inverters such as CMOS inverters, buffers, current mirrors, differential pairs, cascode structures, switches such as CMOS switches, ring oscillators such as differential ring oscillators, or the like.

In some embodiments, different subcircuits of an analog circuit are implemented by identical SUCs having an SUC configuration with different numbers of P-type active regions and N-type active regions. Examples of such an SUC configuration are described with respect to one or more of FIGS. 3A, 3B, 3D where, in an SUC, a number of rows of P-type active regions (or rows of P-type transistors) is different from a number of rows of N-type active regions (or rows of N-type transistors). In at least one embodiment, such an SUC configuration is advantageously suitable for implementing an analog circuit with a unbalanced design, e.g., an analog circuit that includes a large number of current mirrors (i.e., a large number of PMOS transistors), or a large number of decoupling capacitors (i.e., a large number of NMOS transistors for nmoscap), or the like.

In some embodiments, a single gate length design is adopted in which a layout of an analog circuit is implemented using a single SUC. In some embodiments, the SUC has a fixed cell height and/or cell width. Example SUC configurations include, but are not limited to, PPN, NPP, PPNN, NNPP or the like. In at least one embodiment, SUCs are scalable with respect to stack number (e.g., the number of fingers in each group as described herein) and/or finger number (e.g., the total number of fingers over each active region). As a result, it is possible in one or more embodiments to obtain a simplified, uniform layout with a single SUC configuration, reduce the dummy region area, and improve autonomous process flows.

In at least one embodiment, area scaling is achieved by using SUCs of a single SUC configuration for different subcircuits. As a result, it is possible in one or more embodiments to pack different subcircuits of an analog circuit together with easy abutment, without requiring separate dummy surroundings for individual subcircuits, and with a unified dummy region surrounding the entire analog circuit.

In at least one embodiment, performance benefits are achieved, because the SUC-based layout is uniform, with shorter distances and, hence, shorter interconnects between transistors and/or subcircuits. As a result, it is possible in one or more embodiments to mitigate parasitic RC, without causing high gradients in active regions and/or gates.

In at least one embodiment, autonomous flows are achieved and specification definitions and/or DRC checks for autonomous layout flows become easier for SUC-based layouts in accordance with some embodiments, in comparison with analog circuit layouts in accordance with other approaches.

In some embodiments, SUCs and/or SUC configurations described herein are included as part of a PDK, based on fixed layout constructs. In at least one embodiment, the PDK includes one or more fixed features and one or more customizable features. An example fixed feature includes the gate length and width which define the cell height H. A further example fixed feature includes the numbers and/or sequence of P-type active regions and N-type active regions in an SUC, i.e., the SUC configuration of the SUC. Examples of customizable features in a PDK include, but are not limited to, the stack number, finger number, threshold voltage Vth, or the like. Example threshold voltages include, but are not limited to, standard threshold voltage (SVT), low threshold voltage (LVT), ultra-low threshold voltage (ULVT), extreme-low threshold voltage (ELVT), or the like.

In some embodiments, by employing SUCs having the same SUC configuration for implementing different subcircuits, it is possible to provide a limited number of SUC configurations in a PDK, yet all analog circuits are implementable using SUCs of such SUC configurations. In at least one embodiment, an efficient analog/mixed signal design methodology using a single type of SUC is achievable.

In some situations, about 30% of an area of analog circuits in an IC device is occupied by decoupling capacitors, hence, decoupling capacitor area saving is a design consideration. Instead of arranging all decoupling capacitors in a block surrounded by a non-circuit region as described with respect to the other approaches, a layout of an analog circuit in accordance with some embodiments includes decoupling capacitors which are spread out in the layout. For example, as described with respect to FIG. 4A, a plurality of rows of decoupling capacitors (e.g., rows 413, 414, 423, 424 in FIG. 4A) is physically interleaved with a plurality of rows of at least another subcircuit (e.g., rows 411, 412, 415, 416, 421, 422, 425, 426, in FIG. 4A). As also described with respect to FIG. 4A, a transistor not utilized in an SUC-active circuit or subcircuit is configured as a decoupling capacitor. As a result, it is possible in one or more embodiments to achieve a high count of decoupling capacitors, while reducing the area occupied by decoupling capacitors in the analog circuit. In a non-limiting example, about 11% improvement in the decoupling capacitor area is achieved, compared to the other approaches.

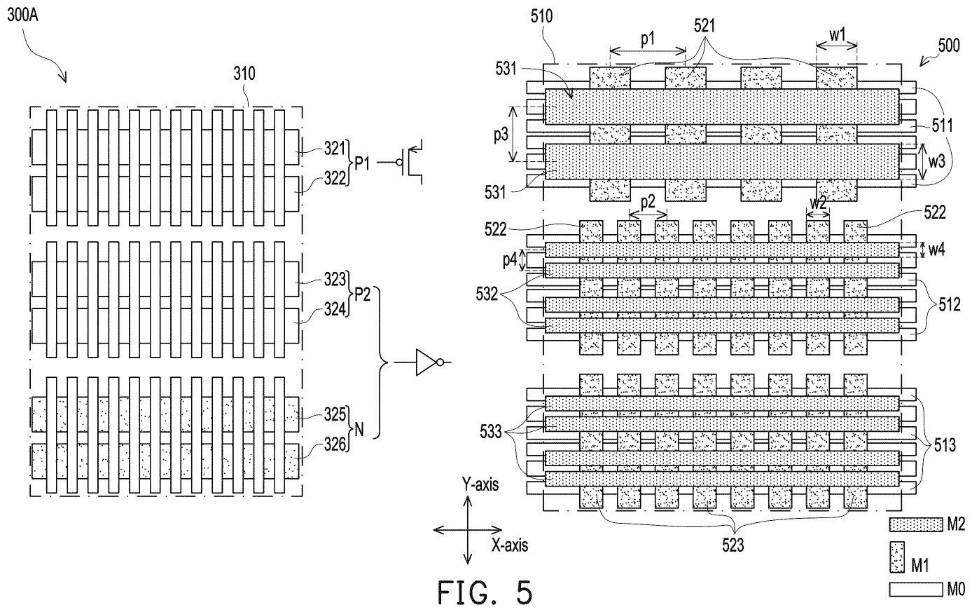

FIG. 5 includes a schematic view of the layout of the SUC 300A and a layout of a corresponding back-end-of-line (BEOL) cell 500, in accordance with some embodiments. BEOL cells are sometimes referred to as metal unit cells. In at least one embodiment, the BEOL cell 500 is stored as a cell in a cell library on a non-transitory computer-readable medium.

The BEOL cell 500 comprises a boundary 510 corresponding to the boundary of an SUC for which the BEOL cell 500 is configured. In the example configuration in FIG. 5, the BEOL cell 500 is configured for the SUC 300A, and the boundary 510 corresponds to the boundary 310 of the SUC 300A. For example, the boundary 510 is exactly the same as the boundary 310 and, in a placement operation, the BEOL cell 500 is placed over the SUC 300A so that the boundary 510 coincides with the boundary 310. In a further, non-limiting example, a BEOL cell configured for another SUC, such as the SUC 300C (NNPP), has a boundary exactly the same as the boundary 370 of the SUC 300C.

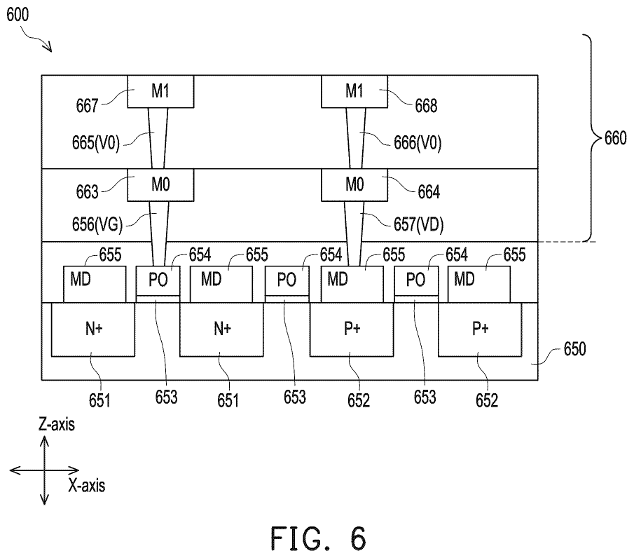

The BEOL cell 500 further comprises, in the boundary 510, conductive patterns of one or more metal layers of a redistribution structure. The redistribution structure is formed in BEOL fabrication over transistors configured by active regions and gates, which are formed in front-end-of-line (FEOL) fabrication. The redistribution structure comprises a plurality of metal layers and a plurality of via layers arranged alternatingly in a thickness direction of the IC device. The lowermost metal layer immediately over the transistors is a metal-zero (M0) layer. In other words, the M0 layer is the lowermost metal layer over, or the closest metal layer to, the active regions and gates. A next metal layer immediately over the M0 layer is a metal-one (M1) layer, a next metal layer immediately over the M1 layer is a metal-two (M2) layer, or the like. Conductors or conductive patterns in the M0 layer are referred to herein as M0 conductors or M0 conductive patterns, conductors or conductive patterns in the M1 layer are referred to herein as M1 conductors or M1 conductive patterns, or the like. A via layer Vn is arranged between and electrically couple the Mn layer and the Mn+1 layer, where n is an integer form zero and up. For example, a via-zero (V0) layer is the lowermost via layer which is arranged between and electrically couple the M0 layer and the M1 layer. Other via layers are V1, V2, or the like. A non-limiting example of a redistribution structure is described with respect to FIG. 6.

In the example configuration in FIG. 5, the BEOL cell 500 includes conductive patterns of the M0 layer, the M1 layer, and the M2 layer. Other configurations where conductive patterns of more, or fewer, metal layers are included in a BEOL cell are within the scopes of various embodiments. In at least one embodiment, vias of one or more via layers, such as the V0 layer and/or the V1 layer, are also included in the BEOL cell 500. In some embodiments, vias are not included in the BEOL cell 500, and are generated in a routing operation.

The conductive patterns of the metal layers in the BEOL cell 500 are configured in accordance with subcircuits to be implemented by the corresponding SUC, e.g., the SUC 300A. In the example configuration in FIG. 5, the SUC 300A is to be used for implementing a PMOS transistor for a current mirror at the active region P1, and an inverter at the active regions P2, N, as described with respect to FIG. 3A. Because the PMOS transistor of the current mirror is configured to handle a greater current than the PMOS transistor and NMOS transistor of the inverter, conductive patterns corresponding to the active region P1 (i.e., corresponding to a current mirror) are configured differently from (e.g., wider than) conductive patterns corresponding to the active regions P2, N (i.e., corresponding to an inverter). Further, because the PMOS transistor and NMOS transistor in the inverter are configured to handle about the same current, the conductive patterns corresponding to the active regions P2, N are configured in the same manner.

Specifically, in the BEOL cell 500, the M0 layer comprises three sets of M0 conductive patterns 511, 512, 513 correspondingly over the active regions P1, P2, N, and extending along the X axis. In the example configuration in FIG. 5, the three sets of M0 conductive patterns 511, 512, 513 have the same configuration, e.g., the M0 conductive patterns 511, 512, 513 have the same metal width in the Y axis, and are spaced from each other along the Y axis by the same metal pitch. Other configurations are within the scopes of various embodiments. For example, in one or more embodiments, the M0 conductive patterns 511 over the active region P1 have at least one of the metal width or the metal pitch greater than the M0 conductive patterns 512, 513 correspondingly over the active regions P2, N.

The M1 layer comprises three sets of M1 conductive patterns 521, 522, 523 correspondingly over the active regions P1, P2, N, and extending along the Y axis. The M1 conductive patterns 521 over the active region P1 have at least one of a metal width or a metal pitch greater than the M1 conductive patterns 522, 523 correspondingly over the active regions P2, N, whereas the M1 conductive patterns 522, 523 have the same metal width and metal pitch. For example, each of the M1 conductive patterns 521 has a metal width w1 along the X axis, each of the M1 conductive patterns 522, 523 has a metal width w2 along the X axis, and w1>w2. Additionally or alternatively, the M1 conductive patterns 521 have a metal pitch p1 which is a distance along the X axis between center lines of immediately adjacent M1 conductive patterns 521, the M1 conductive patterns 522, 523 have a metal pitch p2 which is a distance along the X axis between center lines of immediately adjacent M1 conductive patterns 522, 523, and p1>p2. The greater metal width and/or the grater metal pitch of the M1 conductive patterns 521 result(s) in a smaller number (e.g., 4) of the M1 conductive patterns 521 compared to a number (e.g., 8) of the M1 conductive patterns 522 or the M1 conductive patterns 523.

The M2 layer comprises three sets of M2 conductive patterns 531, 532, 533 correspondingly over the active regions P1, P2, N, and extending along the X axis. The M2 conductive patterns 531 over the active region P1 have at least one of a metal width or a metal pitch greater than the M2 conductive patterns 532, 533 correspondingly over the active regions P2, N, whereas the M2 conductive patterns 532, 533 have the same metal width and metal pitch. For example, each of the M2 conductive patterns 531 has a metal width w3 along the Y axis, each of the M2 conductive patterns 532, 533 has a metal width w4 along the Y axis, and w3>w4. Additionally or alternatively, the M2 conductive patterns 531 have a metal pitch p3 which is a distance along the Y axis between center lines of immediately adjacent M2 conductive patterns 531, the M2 conductive patterns 532, 533 have a metal pitch p4 which is a distance along the Y axis between center lines of immediately adjacent M2 conductive patterns 532, 533, and p3>p4. The greater metal width and/or the grater metal pitch of the M2 conductive patterns 531 result(s) in a smaller number (e.g., 2) of the M2 conductive patterns 531 compared to a number (e.g., 4) of the M2 conductive patterns 532 or the M2 conductive patterns 533.

The described configuration of conductive patterns in the BEOL cell 500 is an example corresponding to a non-limiting specific manner in which the SUC 300A is to be used for implementing specific set of subcircuits, i.e., a current mirror and an inverter. In some embodiments, when the SUC 300A is to be used for implementing another set of subcircuits, e.g., a current mirror and a decoupling capacitor as described with respect to FIG. 4A, rows 411-413, the BEOL cell 500 is configured differently or a different BEOL cell is provided. For example, when the SUC 300A is to be used for implementing a current mirror and a decoupling capacitor as described with respect to FIG. 4A, rows 411-413, the M1 conductive patterns 522 over the active region P2 have the same metal width w1 and the same metal pitch p1 as the M1 conductive patterns 521 over the active region P1, and the M2 conductive patterns 532 over the active region P2 have the same metal width w3 and the same metal pitch p3 as the M2 conductive patterns 531 over the active region P1.

In some embodiments, an IC device comprises an array of BEOL cells, and each BEOL cell is over a corresponding SUC in an array of SUCs as described with respect to FIG. 4A. In at least one embodiment, different BEOL cells are configured for the same SUC and correspond to different manner sin which the SUC is to be used to implement different subcircuits. Such different BEOL cells are included in the array of BEOL cells to configure conductive features that electrically couple the transistors of the underlying SUCs into the intended subcircuits. Because analog metrics are sensitive to metal interconnects, the provision of identical metal interconnects and/or repetitive metal interconnect cells in BEOL cells as described herein makes it possible to achieve better accuracy and speed matching. In some embodiments, the uniformity of an analog circuit layout in both an underlying array of SUCs as well as in an overlying array of BEOL cells improves autonomous flows in the design process.

FIG. 6 is a schematic cross-sectional view of an IC device 600, in accordance with some embodiments. In at least one embodiment, the IC device 600 includes one or more analog circuits configured in one or more manners described with respect to FIGS. 2A-2D, 3A-3D, 4A-4C, 5.

As shown in FIG. 6, the IC device 600 comprises a substrate 650 over which circuit elements and structures corresponding to one or more circuit regions and/or layouts described herein are formed. The substrate 650 has a thickness direction along a Z axis perpendicular to both the X axis and Y axis (not shown in FIG. 6). The substrate 650 comprises, in at least one embodiment, silicon, silicon germanium (SiGe), gallium arsenic, or other suitable semiconductor or dielectric materials. In some embodiments, the substrate 650 is a P-doped substrate. In some embodiments, the substrate 650 is an N-doped substrate. In some embodiments, the substrate 650 is a rigid crystalline material other than a semiconductor material, e.g., diamond, sapphire, aluminum oxide (Al₂O₃), or the like.

The IC device 600 further comprises N-type and P-type dopants added to the substrate 650 to correspondingly form NMOS active regions 651 and PMOS active regions 652. In some embodiments, isolation structures are formed between adjacent active regions. For simplicity, isolation structures are omitted from FIG. 6D. In at least one embodiment, the active regions 651, 652 correspond to one or more of the active regions described herein.

The IC device 600 further comprises various gate structures over the active regions. For example, a gate structure comprises a gate 654, and a corresponding gate dielectric 653 over an active region of the substrate 650. Example materials of the gate dielectric 653, which includes one or more layers, include HfO2, ZrO2, or the like. Example materials of the gate 654 include polysilicon, metal, or the like. In some embodiments, various gate structures of the IC device 600 correspond to one or more of gates described herein. In at least one embodiment, gate structures corresponding to dummy gates include dielectric materials.

The IC device 600 further comprises metal-to-device (MD) contact structures 655 for electrically coupling underlying source/drains of various transistors in the active regions to other circuit elements. In some embodiments, MD contact structures are included in layouts of SUCs.

The IC device 600 further comprises via-to-gate (VG) vias over and in electrical contact with gates, and via-to-device (VD) vias over and in electrical contact with MD contact structures. For example, a representative VG via 656 and a representative VD via 657 are shown in FIG. 6.

The IC device 600 further comprises redistribution structure 660 which is over the VD and VG vias, and comprises a plurality of metal layers M0, M1, . . . and a plurality of via layers V0, V1, . . . arranged alternatingly in the thickness direction of the substrate 650, i.e., along the Z axis. The redistribution structure 660 further comprises various interlayer dielectric (ILD) layers (not shown or numbered) in which the metal layers and via layers are embedded. The metal layers and via layers of the interconnect structure 660 are configured to electrically couple various elements or circuits of the IC device 600 with each other, and/or with external circuitry. For simplicity, metal layers and via layers above the M1 layer are omitted in FIG. 6. In the example configuration in FIG. 6, the M0 layer comprises M0 conductive patterns 663, 664 correspondingly over and in electrical contact with the VG via 656 and VD via 657. The V0 layer comprises V0 vias 665, 666 correspondingly over and in electrical contact with the M0 conductive patterns 663, 664. The M1 layer comprises M1 conductive patterns 667, 668 correspondingly over and in electrical contact with the V0 vias 665, 666.

The MD contact structures, VG vias, VD vias, conductive patterns in one or more metal layers and corresponding vias in one or more via layers are examples of conductive features which electrically couple the underlying transistors into subcircuits and further electrically couple the subcircuits into one or more analog circuits, as described herein.

FIG. 7 is a flow chart of a portion of an IC design flow 700, in accordance with some embodiments. In some embodiments, the IC design flow 700 corresponds to one or more operations of the IC design flow 100, e.g., the APR at operation 130. In some embodiments, the IC design flow 700 is performed entirely automatically by a programmed processor. In at least one embodiment, the IC design flow 700 is performed automatically by a programmed processor using inputs provided by a human designer. In some embodiments, the IC design flow 700 is performed to generate a layout including one or more analog circuits as described with respect to FIGS. 4A-4C, using identical SUCs having a same SUC configuration as described with respect to FIGS. 3A-3D. In at least one embodiment, one or more operations of the IC design flow 700 as described herein are omitted.

At operation 710, blocks or subcircuits of an analog circuit are identified. For example, when the analog circuit is an ICO 200A as described with respect to FIG. 2A, three blocks or subcircuits including current mirror, DRO and decoupling capacitor are identified. In some embodiments, the identification of subcircuits of an analog circuit is an input provided to the APR tool, e.g., by a human designer.

At operation 712, floor-planning is performed with focus on at least one critical block of the analog circuit. In some embodiments, among the blocks or subcircuits identified at operation 710, a critical block is one the speed of which has greater impact on the overall speed of the analog circuit than the other subcircuits. For example, the critical block of the ICO is the DRO. A floor plan for placement of subcircuits of the ICO is generated with focus on the DRO. For example, as shown in and described with respect to FIGS. 4A, 4C, a placement site for the DRO is arranged in the middle of a circuit region in which the ICO is to be configured, whereas placement sites for the current mirror and decoupling capacitor are arranged on opposite sides, or around, the placement site for the DRO.

At operation 714, an SUC configuration for implementing the ICO is selected. In an example, it is determined that the current mirror comprises PMOS transistors with high driving strength, the DRO comprises a balanced arrangement of PMOS transistors and NMOS transistors in terms of quantity and driving strength, and the decoupling capacitor comprises NMOS transistors. Given the requirement for PMOS transistors with high driving strength in the current mirror, an SUC configuration with a greater number of P-type active regions is selected. For example, the SUC configuration 381, or PPN, is selected. In some embodiments, the selection of the SUC configuration for implementing an analog circuit is an input provided to the APR tool, e.g., by a human designer.

At operation 716, a maximum stack number in the design of the analog circuit is determined. For example, given the driving strength requirements for the current mirror, DRO and decoupling capacitor, PMOS transistors of the current mirror require a stack number of 12 fingers, whereas the transistors of the DRO and the decoupling capacitor require a lower stack number of two or three fingers in each group. As a result, the maximum stack number is 12.

At operation 718, the cell width W of each SUC is determined based on the maximum stack number, e.g., 12 fingers, determined at operation 716. In some embodiments, when the exact number of subcircuits to be realized (e.g., 1000 transistors MP1 in the current mirror) is not obtainable with a single cell width, additional SUCs with the same SUC configuration (e.g., PPN) but with a different cell width are used to match the exact number of subcircuits to be realized.

In some embodiments, multiple instances of an SUC having the SUC configuration selected at operation 714, the number of fingers per active region and the cell width correspondingly determined at operations 716, 718, and a predetermined cell height, are placed in accordance with the floor plan generated at operation 712.

At operation 720, P-type and N-type active regions of each SUC are assigned to particular blocks in the circuit. For example, as described with respect to FIGS. 4A, 4B, P-type and N-type active regions of each SUC are assigned differently depending on whether the SUC is in the DRO blocks (e.g., the block 440) or outside the DRO blocks. Specifically, for each SUC in the DRO blocks, one P-type active region is assigned to implement the current mirror, whereas the other P-type active region and the adjacent N-type active region are assigned to implement inverters for the DRO. For each SUC outside the DRO blocks, both P-type active regions are assigned to implement the current mirror, whereas the N-type active region is assigned to implement a decoupling capacitor.

At operation 722, SUCs are configured to complete the critical block(s) first, i.e., before the other, less critical or non-critical, blocks or subcircuits of the analog circuit. For example, the DRO is the critical block and SUCs for DRO implementation are configured to complete the DRO first, before the current mirror and decoupling capacitors. In at least one embodiment, a routing operation is performed to generate conductive features electrically coupling the transistors of the SUCs in the DRO block into a DRO. In at least one embodiment, a balanced common centroid layout, as described with respect to the subregion 435 and/or the block 440 in FIG. 4B, is obtained. As a result, it is possible in one or more embodiments to balance out process variations potentially affecting one side of the layout more than the other, and to improve matching between transistors in at least the DRO block.

At operation 724, remaining SUCs are configured to complete the other blocks of the analog circuit. For example, the routing operation is performed to generate conductive features electrically coupling the transistors of the SUCs outside the DRO block into a current mirror and decoupling capacitors. In some embodiments, operation 724 is performed using a symmetric layout style.

At operation 726, devices or transistors not used in active blocks of the analog circuit are configured as decoupling capacitors. In at least one embodiment, an active block of an analog circuit is a subcircuit configured to perform signal processing. For example, the DRO and current mirror are active blocks of the ICO. In some embodiments, decoupling capacitors are not considered as an active block or subcircuit. The transistors not used in the active blocks are electrically coupled into decoupling capacitors by conductive features generated, e.g., in the routing operation. As a result of operation 726, transistors not designated for implementing an active block (e.g., the current mirror and DRO) are configured as decoupling capacitors which are interspersed with transistors of the active blocks. This is a distinction from other approaches in accordance with which decoupling capacitors are placed in empty areas.

At operation 728, the routing operation is finished to complete required interconnects in a redistribution structure, and a layout containing the analog circuit is obtained. One or more advantages described herein are achievable by IC devices corresponding to a layout obtained from the IC design flow 700.

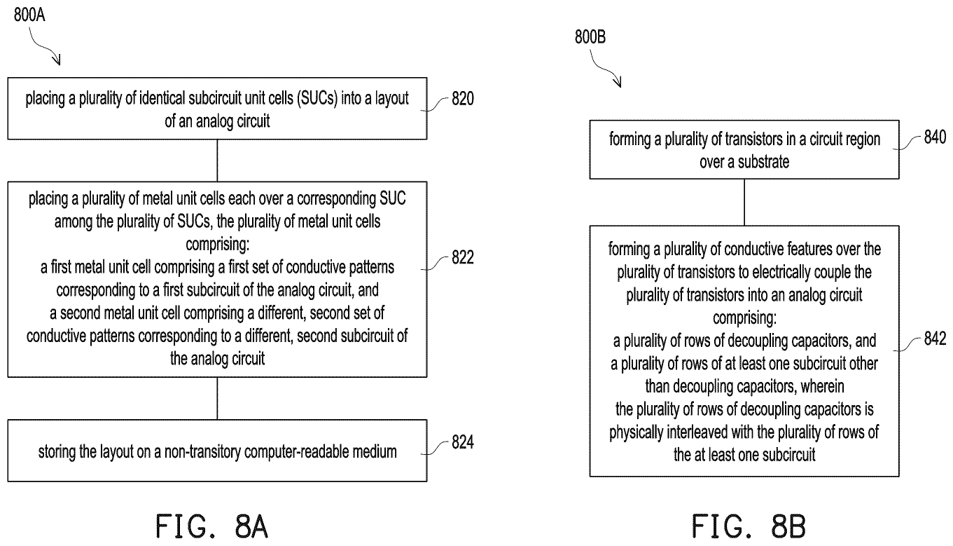

FIG. 8A is a flowchart of a method 800A, in accordance with some embodiments. In some embodiments, the method 800A is performed at least partially by at least one processor, and/or comprises at least a portion of one or more of the IC design flows described with respect to FIGS. 1, 7.

At operation 820, a plurality of identical subcircuit unit cells (SUCs) is placed into a layout of an analog circuit of an IC device. For example, as described with respect to FIG. 4A, an array of SUCs 410 is generated by placing multiple instances of the same SUC in abutment with each other.

At operation 822, a plurality of metal unit cells is placed each over a corresponding SUC among the plurality of SUCs. The plurality of metal unit cells comprises a first metal unit cell comprising a first set of conductive patterns corresponding to a first subcircuit of the analog circuit, and a second metal unit cell comprising a second set of conductive patterns different from the first set of conductive patterns and corresponding to a second subcircuit of the analog circuit, the second subcircuit different from the first subcircuit. An example of a first metal unit cell, or BEOL cell, is described with respect to FIGS. 4B, 5, where a BEOL cell 500 comprises a first set of conductive patterns over the underlying SUC 300A, and corresponding to a PMOS transistor of a current mirror and an inverter. An example of a second metal unit cell is described with respect to FIGS. 4A, 5, where a BEOL cell comprises a second set of conductive patterns over the underlying SUC 300A, and corresponding to PMOS transistors of a current mirror and a decoupling capacitor. The provision of different BEOL cells for the same SUC makes it possible, in one or more embodiments, to implement different subcircuits using identical SUCs, which improves autonomous flows in the design process.

At operation 824, the obtained layout is stored on a non-transitory, computer-readable recording medium. One or more advantages described herein are achievable by a layout generated by the method 800A, and/or by IC devices manufactured using such a layout, in accordance with some embodiments.

FIG. 8B is a flowchart of a method 800B, in accordance with some embodiments. In some embodiments, the method 800B is a manufacturing process, which is performed using a manufacturing system discussed below, and in which at least one of (A) one or more photolithographic exposures are made, (B) one or more semiconductor masks are fabricated, or (C) one or more components in a layer of an IC device are fabricated. In some embodiments, IC devices are manufactured by the method 800B based on one or more IC layouts generated by the IC design flows 100, 700, method 800A or as described herein.

At operation 840, a plurality of transistors is formed in a circuit region over a substrate, for example, as described with respect to FIG. 6. For example, active regions 651, 652 including source/drains and a channel therebetween are formed over a substrate 650. In some embodiments, the active region includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material. In some embodiments, an active region comprises a nano-sheet structure, e.g., a continuous volume of one or more layers of one or more semiconductor materials. In various embodiments, individual nano-sheet layers include a single monolayer or multiple monolayers of a given semiconductor material. In at least one embodiment, the active regions are formed as part of CFET structures.

Next, a plurality of gates is formed over and transverse to the plurality of active regions, to configure a plurality of transistors. For example, gates 654 are formed to extend over and across the active regions 651, 652 to configure therewith various transistors. In some embodiments, a gate is a part of a gate structure and includes one or more conductive materials, e.g., polysilicon, copper (Cu), aluminum (Al), tungsten (W), cobalt (Co), ruthenium (Ru), or one or more other metals or other suitable materials. The gate structure further comprises a gate dielectric layer including one or more insulating materials, e.g., silicon dioxide, silicon nitride (Si₃N₄), and/or one or more other suitable material such as a low-k material having a k value less than 3.8, or a high-k material having a k value greater than 3.8, such as aluminum oxide (Al₂O₃), hafnium oxide (HfO₂), tantalum pentoxide (Ta₂O₅), or titanium oxide (TiO₂).

At operation 842, a plurality of conductive features is formed over the plurality of transistors to electrically couple the plurality of transistors into an analog circuit. Examples of conductive features are described with respect to FIG. 6, and include various MD contact structures, VG vias, VD vias, conductive patterns in one or more metal layers M0, M1, or the like, and vias in one or more via layers V0, V1, or the like. The conductive features electrically couple the underlying transistors into an analog circuit comprising a plurality of rows of decoupling capacitors, and a plurality of rows of at least one subcircuit other than decoupling capacitors, wherein the plurality of rows of decoupling capacitors is physically interleaved with the plurality of rows of the at least one subcircuit. For example, as described with respect to FIG. 4A, an analog circuit (e.g., an ICO) comprises a plurality of rows 413, 414, 423, 424 of decoupling capacitors and a plurality of rows 411, 412, 415, 416, 421, 422, 425, 426 of a different subcircuit, e.g., a current mirror. The rows 413, 414, 423, 424 of decoupling capacitors and the rows 411, 412, 415, 416, 421, 422, 425, 426 of the current mirror are physically interleaved at least along the Y axis, as illustrated the example configuration of FIG. 4A. In some embodiments, on opposite sides of the subregion 435 (DRO Block) in the X axis, the N-type active regions configure additional rows of decoupling capacitors and the P-type active regions configure additional rows of a current mirror which are physically interleaved with the additional rows of decoupling capacitors along the Y axis. In some embodiments, one or more advantages described herein are achievable by IC devices manufactured in accordance with the method 800B.

In at least one embodiment, operation 840 comprises forming further transistors in a dummy region over the substrate, wherein the dummy region surrounds a circuit region containing the analog circuit. For example, as described with respect to FIG. 4C, a dummy region 470 is formed around a circuit region 460 including the analog circuit. In some embodiments, operation 842 is performed such that transistors in the circuit region 460 are electrically coupled into subcircuits and then into the analog circuit, but without electrically coupling the further transistors in the dummy region 470 into a circuit. In other words, the further transistors in the dummy region 470 are configured as dummy transistors.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

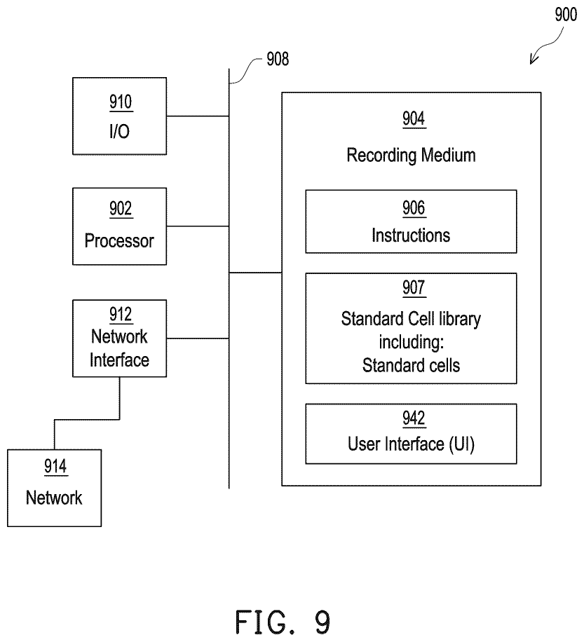

FIG. 9 is a block diagram of an electronic design automation (EDA) system 900 in accordance with some embodiments.

In some embodiments, EDA system 900 includes an APR system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable recording medium 904. Recording medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable recording medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable recording medium 904 are capable of connecting to external elements via network 914. Processor 902 is configured to execute computer program code 906 encoded in computer-readable recording medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable recording medium 904 is an electronic, magnetic, optical, electromagnetic, infrared, and/or a semiconductor system (or apparatus or device). For example, computer-readable recording medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 904 includes a compact disk-read only memory (CD-ROM), a compact disk-read/write (CD-R/W), and/or a digital video disc (DVD).

In one or more embodiments, recording medium 904 stores computer program code 906 configured to cause system 900 (where such execution represents (at least in part) the EDA tool) to be usable for performing a portion or all of the noted processes and/or methods. In one or more embodiments, recording medium 904 also stores information which facilitates performing a portion or all of the noted processes and/or methods. In one or more embodiments, recording medium 904 stores library 907 of cells including such cells as disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a UI through I/O interface 910. The information is stored in computer-readable recording medium 904 as user interface (UI) 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

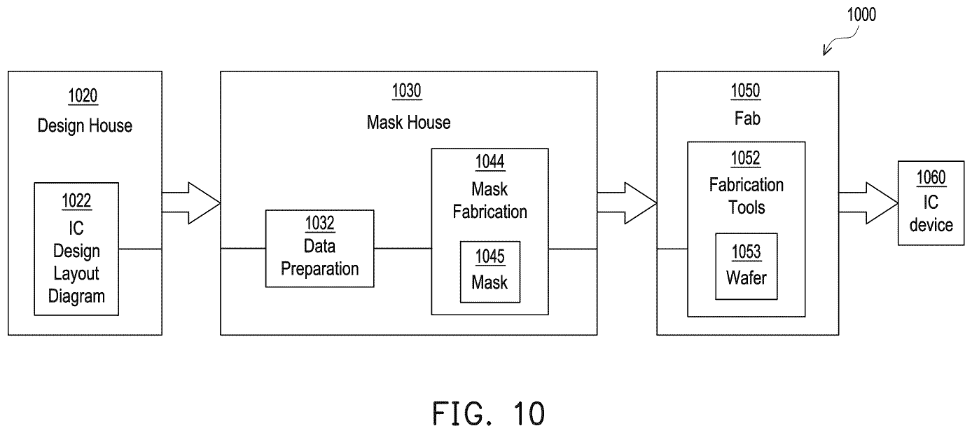

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place-and-route operation. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an integrated circuit (IC) device comprises an array of subcircuit unit cells (SUCs) having a same SUC configuration. The SUC configuration comprises a first number of P-type active regions and a second number of N-type active regions, and the first number is different from the second number. The array of SUCs comprises: first SUCs configuring a first subcircuit of an analog circuit, and second SUCs configuring a second subcircuit of the analog circuit, the second subcircuit different from the first subcircuit.

In some embodiments, an integrated circuit (IC) device comprises: a circuit region comprising different subcircuits of an analog circuit, and a dummy region surrounding the circuit region, the dummy region comprising dummy transistors. The circuit region is free of dummy transistors separating a subcircuit among the subcircuits of the analog circuit from further subcircuits among the subcircuits of the analog circuit.

In some embodiments, a method comprises: forming a plurality of transistors in a circuit region over a substrate, and forming a plurality of conductive features over the plurality of transistors. The plurality of conductive features electrically couples the plurality of transistors into an analog circuit. The analog circuit comprises: a plurality of rows of decoupling capacitors, and a plurality of rows of at least one subcircuit other than decoupling capacitors. The plurality of rows of decoupling capacitors is physically interleaved with the plurality of rows of the at least one subcircuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
an array of subcircuit unit cells (SUCs) having a same SUC configuration, wherein
the SUC configuration comprises a first number of P-type active regions and a second number of N-type active regions, the first number different from the second number, and
the array of SUCs comprises:
first SUCs configuring a first subcircuit of an analog circuit, and
second SUCs configuring a second subcircuit of the analog circuit, the second subcircuit different from the first subcircuit.

2. The IC device of claim 1, wherein
the array of SUCs further comprises third SUCs configuring a third subcircuit of the analog circuit, the third subcircuit different from the second subcircuit and the first subcircuit.

3. The IC device of claim 2, wherein
at least one of the first subcircuit, the second subcircuit or the third subcircuit is selected from the group consisting of: a P-type transistor, an N-type transistor, a P-type decoupling capacitor, an N-type decoupling capacitor, an inverter, a current mirror, a buffer, a differential pair, a cascode structure, a switch, and a ring oscillator.

4. The IC device of claim 1, wherein
the analog circuit is selected from the group consisting of: a current-controlled oscillator, a voltage-controlled oscillator, an operational transconductance amplifier, a sense amplifier comparator, a transadmittance amplifier, a transimpedance amplifier, a digital-to-analog converter (DAC), and a band-gap reference circuit.

5. The IC device of claim 1, wherein
in the SUC configuration, the first number of P-type active regions and the second number of N-type active regions are arranged consecutively.

6. The IC device of claim 1, wherein
the SUC configuration is:
a first SUC configuration comprising a first P-type active region, a second P-type active region and an N-type active region arranged consecutively, or
a second SUC configuration comprising a first N-type active region, a second N-type active region and a P-type active region arranged consecutively.

7. The IC device of claim 1, further comprising:
a dummy region surrounding the array of SUCs, the dummy region comprising dummy transistors.

8. The IC device of claim 1, further comprising:
a dummy region surrounding the array of SUCs, wherein
the dummy region comprises SUCs having the same SUC configuration as in the array of SUCs, and
the SUCs of the dummy region comprise dummy transistors.

9. The IC device of claim 1, further comprising:
a metal layer over the array of SUCs, wherein
the metal layer comprises:
a set of first conductive patterns corresponding to the first subcircuit,
a set of second conductive patterns corresponding to the second subcircuit, and
at least one of
a width of each first conductive pattern in the set of first conductive patterns is different from a width of each second conductive pattern in the set of second conductive patterns,
a number of the first conductive patterns in the set of first conductive patterns is different from a number of the second conductive patterns in the set of second conductive patterns, or
a pitch between immediately adjacent first conductive patterns in the set of first conductive patterns is different from a pitch between immediately adjacent second conductive patterns in the set of second conductive patterns.

10. The IC device of claim 9, further comprising:
an array of metal unit cells each including the set of first conductive patterns and the set of second conductive patterns, wherein
each metal unit cell in the array of metal unit cells is over a corresponding SUC in the array of SUCs.

11. An integrated circuit (IC) device, comprising:
a circuit region comprising different subcircuits of an analog circuit; and
a dummy region surrounding the circuit region, the dummy region comprising dummy transistors, wherein
the circuit region is free of dummy transistors separating a subcircuit among the subcircuits of the analog circuit from further subcircuits among the subcircuits of the analog circuit.

12. The IC device of claim 11, wherein
the circuit region is free of dummy transistors surrounding a subcircuit among the subcircuits of the analog circuit.

13. The IC device of claim 11, wherein
at least one of the subcircuits is selected from the group consisting of: a P-type transistor, an N-type transistor, a P-type decoupling capacitor, an N-type decoupling capacitor, an inverter, a current mirror, a buffer, a differential pair, a cascode structure, a switch, and a differential ring oscillator (DRO).

14. The IC device of claim 11, wherein
the analog circuit is selected from the group consisting of: a current-controlled oscillator, a voltage-controlled oscillator, an operational transconductance amplifier, a sense amplifier comparator, a transadmittance amplifier, a transimpedance amplifier, a digital-to-analog converter (DAC), and a band-gap reference circuit.

15. The IC device of claim 11, wherein
in the circuit region, transistors not configuring any subcircuit among the subcircuits of the analog circuit are configured as decoupling capacitors.

16. The IC device of claim 11, wherein
the circuit region comprises an array of subcircuit unit cells (SUCs) having a same SUC configuration, and the different subcircuits of the analog circuit are configured by the SUCs having the same SUC configuration.

17. The IC device of claim 16, wherein
an SUC in the array of SUCs comprises:
one or more first transistors configuring at least one subcircuit among the subcircuits of the analog circuit, and
one or more second transistors not configuring any subcircuit among the subcircuits of the analog circuit, wherein the one or more second transistors are configured as one or more decoupling capacitors.

18. A method, comprising:
forming a plurality of transistors in a circuit region over a substrate; and
forming a plurality of conductive features over the plurality of transistors, wherein
the plurality of conductive features electrically couples the plurality of transistors into an analog circuit,
the analog circuit comprises:
a plurality of rows of decoupling capacitors, and
a plurality of rows of at least one subcircuit other than decoupling capacitors, and
the plurality of rows of decoupling capacitors is physically interleaved with the plurality of rows of the at least one subcircuit.

19. The method of claim 18, further comprising:
forming a plurality of further transistors in a dummy region over the substrate, wherein
the dummy region surrounds the circuit region, and
the forming the plurality of conductive features is performed without electrically coupling the plurality of further transistors in the dummy region into a circuit, to configure the plurality of further transistors as dummy transistors.

20. The method of claim 18, wherein
in the circuit region, the plurality of transistors comprises:
a first number of rows of P-type transistors, and
a second number of rows of N-type transistors, the second number different from the first number.
